(19) United States
(12) Patent Application Publication
(10) Pub. No.: US 2011/0308580 A1
(43) Pub. Date: Dec. 22, 2011

(54) Ferroic materials having domain walls and related devices

(75) Inventors: Jan Seidel, Oakland, CA (US); Ramamoorthy Ramesh, Moraga, CA (US); Lane Martin, Champaign, IL (US); Seung-Yeul Yang, Albany, CA (US)

(73) Assignee: The Regents of the University of California, Oakland, CA (US)

(21) Appl. No.: 12/930,507

(22) Filed: Jan. 7, 2011

Related U.S. Application Data
(60) Provisional application No. 61/297,675, filed on Jan. 22, 2010.

(51) Int. Cl. H01L 31/02; G11B 5/65

(52) U.S. Cl. 136/252; 428/836.1

(57) ABSTRACT

Ferroic materials and methods for diverse applications including nanoscale memory, logic and photovoltaic devices are described. In one aspect, ferroic thin films including insulating domains separated by conducting domain walls are provided, with both the insulating domains and conducting domain walls intrinsic to the ferroic thin films. The walls are on the order of about 2 nm wide, providing virtually two dimensional conducting sheets through the insulating material. Also provided are methods of writing, reading, erasing and manipulating conducting domain walls. According to various embodiments, logic and memory devices having conducting domain walls as nanoscale features are provided. In another aspect, ferroic thin films having photovoltaic activity are provided. According to various embodiments, photovoltaic and optoelectronic devices are provided.

### CROSS-REFERENCE TO RELATED APPLICATION

This application claims benefit under 35 USC §119(e) of U.S. Provisional Application No. 61/297,675, filed Jan. 22, 2010, incorporated by reference herein.

### STATEMENT OF GOVERNMENT SUPPORT

This invention was made with government support under Contract No. DE-AC02-05CH11231 awarded by the U.S. Department of Energy. The government has certain rights in the invention.

### BACKGROUND OF THE INVENTION

Ferroic materials include ferromagnets, ferroelectrics, and ferroelastics. Multiferroic materials exhibit more than one type of ferroic order in the same phase. The defining characteristic of a ferroic material is an order parameter (electric polarization in ferroelectrics, magnetization in ferromagnets, or spontaneous strain in ferroelastics) that has different, energetically equivalent orientations; the orientation of which can be selected using an applied field. A ferroic material may have domains of differently oriented regions, separated by domain walls, coexisting in a sample.

### SUMMARY OF THE INVENTION

Ferroic materials and methods for diverse applications including nanoscale memory, logic and photovoltaic devices are described. In one aspect, ferroic thin films including insulating domains separated by conducting domain walls are provided, with both the insulating domains and conducting domain walls intrinsic to the ferroic thin films. The walls are on the order of about 2 nm wide, providing virtually two dimensional conducting sheets through the insulating material. Also provided are methods of writing, reading, erasing and manipulating conducting domain walls. According to various embodiments, logic and memory devices having conducting domain walls as nanoscale features are provided. In another aspect, ferroic thin films having photovoltaic activity are provided. According to various embodiments, photovoltaic and optoelectronic devices are provided. These and other features and advantages of the present invention will be described in more detail below with reference to the associated drawings.

### BRIEF DESCRIPTION OF THE DRAWINGS

FIG. 1a is a schematic representation of domain walls in a ferroic thin film according to certain embodiments.

FIG. 1b is an out-of-plane piezoresponse force microscopy (PFM) image of a written domain pattern in a monodomain BFO (110) film showing the out-of-plane polarization component of the domains to be either down, labeled as “D” (white), or up, labeled as “U” (black).

FIG. 1c is an in-plane PFM image of a written domain pattern in a monodomain BFO (110) film showing all three types of domain walls, i.e. 71°, 109°, and 180°, as inferred from the combination of both out-of-plane and in-plane PFM images. In this image, both the out-of-plane (U or D) component as well as in-plane projection of the polarization direction (shown as an arrow) are also labeled.

FIG. 1d is a conducting-atomic force microscopy (c-AFM) image corresponding to the written domain pattern imaged in FIGS. 1b and 1c. The image shows conduction at both 109° and 180° domain walls and the absence of conduction at the 71° domain walls.

FIG. 2a is schematic illustration of a c-AFM setup that may be used in accordance with certain embodiments.

FIG. 2b shows an out-of plane PFM image of a written 180° domain in a monodomain BFO (110) sample (upper) and corresponding c-AFM current maps for −1V, −1.5V, and −2V sample bias done with a Pt-coated tip.

FIG. 2c shows I-V curves taken both on the domain wall and off the domain wall. These reveal Schottky-like behavior.

FIG. 2d shows time-dependence of the current both on the wall and off the wall at an applied sample bias of −2V. Results are qualitatively similar for N-doped diamond tips.

FIG. 3a is a schematic of a 109° domain wall.

FIG. 3b shows the extracted a and c lattice parameter for each unit cell across the 109° domain wall, with the lower data series the a parameter and the upper data series the c parameter.

FIG. 3c shows the extracted Fe-ion displacement relative to the Bi lattice for each unit cell across the domain wall.

FIG. 4a shows a schematic illustration (left) of in-plane electrode structure and how scanning probe tips can be used to controllably create conductive domain wall features between electrodes. Images on right show AFM (top) and out-of-plane PFM (bottom) contrast for this written domain area on a BFO (110) sample.

FIG. 4b shows current-voltage characteristics of devices measured between the two in-plane electrodes. This shows that the current can be incrementally controlled through creating or erasing the conducting domain walls.

FIG. 5 shows the dependence of current on oxygen content in BFO films.

FIG. 6 illustrate examples in which a pattern of conducting and non-conducting domain walls is formed in a multiferroic film using spacing of the domain walls in the film and controlling the type of domain wall (conducting or non-conducting) written.

FIG. 7 shows an example of a patterned media disk including a multiferroic thin film according to certain embodiments.

FIG. 8 shows an example of a patterned media material including a multiferroic thin film configured to be addressed by parallel read/write heads.

FIG. 9 shows examples of devices in which domain wall patterns are moved via applied electric fields.

FIG. 10a shows a PFM image of an ordered array of 71° domain walls in a BFO thin film created with a heteroepitaxial growth process.

FIG. 10b shows a schematic depiction of the ordered array of 71° domain walls imaged in FIG. 10a.

FIG. 10c shows a PFM image of an ordered array of 109° domain walls in a BFO thin film created with a heteroepitaxial growth process.

FIG. 10d shows a schematic depiction of the ordered array of 109° domain walls imaged in FIG. 10c.

FIG. 11a shows a schematic of a photovoltaic device configured for electric transport measurements perpendicular to domain walls of an ordered array of 71° domain walls in a BFO thin film. FIG. 11a also shows a corresponding I-V measurement.

FIG. 11b shows a schematic of a photovoltaic device configured for electric transport measurements parallel to domain walls of an ordered array of 71° domain walls in a BFO thin film. FIG. 11b also shows a corresponding I-V measurement.

FIG. 12a is a plot showing V_{OC} as a function of electrode spacing for four different samples: 71° domain wall samples with thicknesses of 100 nm, 200 nm and 500 nm, as well as a monodomain BFO film having no domain walls.

FIG. 12b is a plot showing potential drop across a domain wall in relation to domain width for a BFO thin film sample having an ordered array of 71° domain walls.

FIG. 13a is a schematic of a model domain structure showing a series of 71° domain walls.

FIG. 13b shows the corresponding position of the valence (VB) and conduction (CB) bands of the domain structure shown in FIG. 13a in dark conditions.

FIG. 13c shows the evolution of the band structure shown in FIG. 13b upon illumination of the domain wall array.

FIG. 13d provides a schematic showing a detailed picture of a build-up of photo excited charges at a domain wall.

FIG. 14a is a plot showing light characterization of an as-grown device structure having parallel geometry as grown (domain walls parallel to the electronic transport path), prior to and after application of +/−200 V pulses.

FIG. 14b shows corresponding PFM images of the as-grown, 200 V poled, and −200 V poled device structures characterized in FIG. 14a.

FIG. 15a is a schematic of a 71° domain pattern, with large arrows showing the net ferroelectric polarization, and including a schematic of a detailed 71° domain structure.

FIG. 15b shows out-of-plane and in-plane PFM images of a 71° domain pattern.

FIG. 15c is a hysteresis loop of CoFe on a 71° domain wall sample.

FIG. 16a is a schematic of a 109° domain pattern with different domain clusters, with large arrows showing the net ferroelectric polarization within each cluster, and including a schematic of a detailed 109° domain structure with one domain cluster.

FIG. 16b shows out-of-plane and in-plane PFM images of a 109° domain pattern.

FIG. 16c is a hysteresis loop of CoFe on a 109° domain wall sample.

FIG. 17a is a schematic illustrating experimental geometries used to take photoemission electron microscopy (PEEM) images of 109° domain walls with circular polarized x-rays.

FIG. 17b shows an in-plane PFM image of an area where the 109° domain walls are electrically erased.

FIG. 17c is a PEEM image obtained from the ratio of LCP and RCP images at the first incident angle of the x-ray.

FIG. 17d is a PEEM image at the second incident angle of the x-ray, 180° away with respect to the first angle with respect to the sample normal.

FIG. 17e shows XMCD between the selected pair of boxes in the PEEM image. XMCD is calculated from the asymmetry of XAS curves between each pair of boxed areas. A typical x-ray absorption spectrum showing the L_{2,3} edges for Fe is depicted. Curves showing the asymmetry difference between locations inside and outside the switched box and the asymmetry difference between locations inside the switched box for measurements done with RCP and LCP.

FIG. 18a is a schematic of a device structure having a current path parallel to domain walls.

FIGS. 18b-18d are plots including current-temperature curves in a transport study on 109° domain walls.

FIG. 19a shows anisotropic magnetoresistance in different direction of external magnetic field as illustrated in FIG. 18a at a temperature of 30K.

FIG. 19b is a schematic of ferroelectric polarization and the evolution of antiferromagnetic easy axis within one single domain wall with the domain wall plane in (100).

### DETAILED DESCRIPTION

Embodiments described herein include ferroic materials including domain walls and related media and devices. Ferroic materials include ferromagnets, ferroelectrics, and ferroelastics. Multiferroic materials exhibit more than one type of ferroic order in the same phase. The defining characteristic of a ferroic material is an order parameter (electric polarization in ferroelectrics, magnetization in ferromagnets, or spontaneous strain in ferroelastics) that has different, energetically equivalent orientations; the orientation of which can be selected using an applied field. A ferroic material may have domains of differently oriented regions, separated by domain walls, coexisting in a sample.

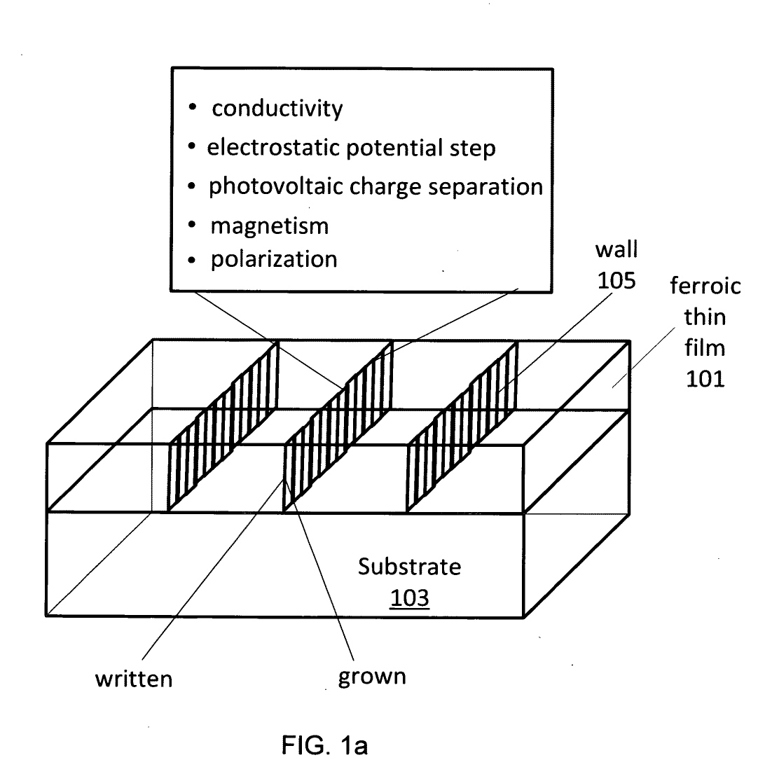

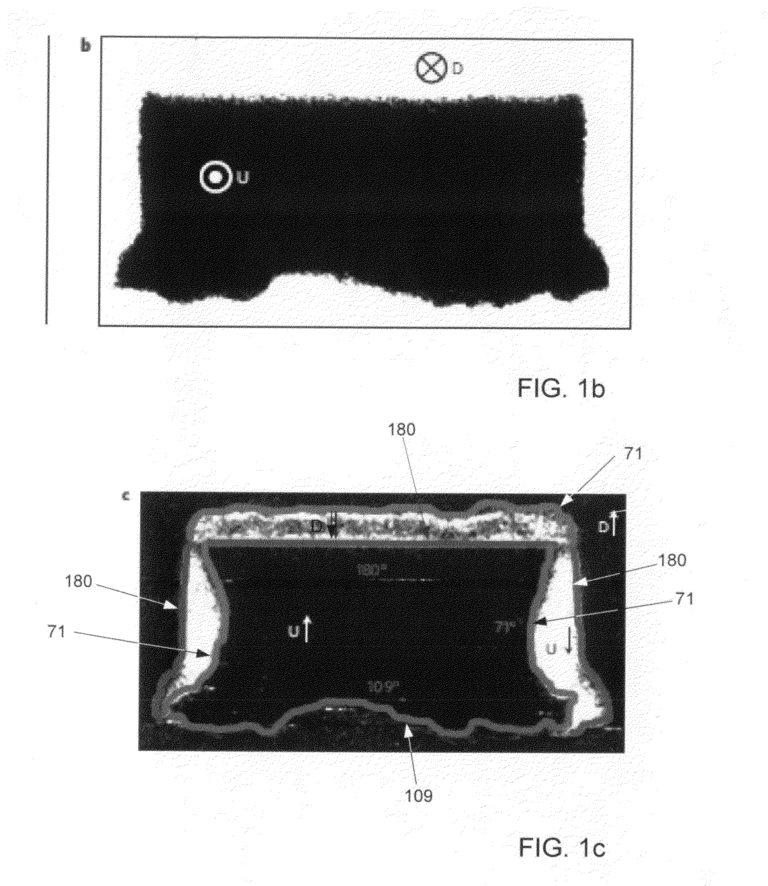

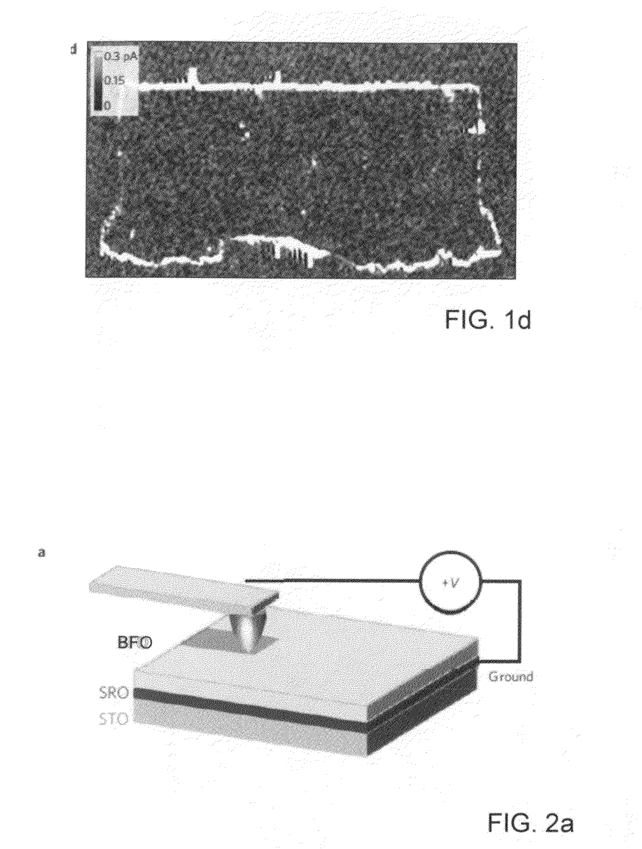

FIG. 1a is a schematic diagram illustrating domain walls in thin film of a ferroic material according to various embodiments. A thin film 101 is disposed on substrate 103 and includes domain walls 105. As described further below, domain walls 105 separate domains of differently oriented regions with the thin film. As indicated in FIG. 1a, a domain wall may exhibit various characteristics, including conductivity, electrostatic potential step, photovoltaic charge separation and magnetism. Depending on the particular ferroic material and the orientation of the domain wall, it may exhibit one or more of these characteristics. The below description provides ferroic materials having conductive domain walls, photovoltaic activity, magnetic domain walls and magnetotransport, and related devices. Ferroic thin films may be grown, deposited or otherwise formed on appropriate substrates including silicon-based substrates, glass-based substrates, and the like. As indicated in FIG. 1a, domain walls may be grown with the thin film, or formed in an existing thin film.

While the description below refers in certain instances to multiferroics and ferroelectrics, the thin films described herein are not so limited but include any material that has at least one order parameter, such as magnetism, ferroelectric order, ferroelastic order, and that form domains and domain walls. Accordingly, wherein the description refers to multiferroics, in certain embodiments, a material having a only a single ferroic property may be used instead, for example, if it has domain walls and exhibits the particular property of interest. Similarly, wherein the description refers to ferroelectrics, in certain embodiments, a material exhibiting a different order parameter may be used instead, for example, if it has domain walls and exhibits the particular property of interest.

Embodiments of the invention include ferroic materials having domain walls that have electrical conductivity. Prior to this invention, such electrically conductive domain walls had never been observed. According to various embodiments, the materials are incorporated into nanoscale logic and memory devices, with the conducting domain walls providing nanoscale logic and memory elements of these devices. In certain embodiments, the conducting domain walls are writable, readable, erasable and manipulable.

Conducting domain walls in multiferroic bismuth ferrite are described below; however the invention is not so limited and includes other multiferroic and ferroelectric materials having conducting domain walls. Examples of these are also described further below. Multiferroic bismuth ferrite (BiFeO₃ or BFO) is a room temperature G-type antiferromagnet (T_{N}˜650 K) and a rhombohedral ferroelectric (T_{C}˜1103 K), with a large spontaneous ferroelectric polarization (˜90 μC/cm²) along the 111-direction. Such rhombohedral ferroelectrics possess 71°, 109°, and 180° domain walls forming on {101}, {100}, and planes that satisfy the requirement that ±h±k+l=0, respectively. All three wall orientations have been observed in BFO.

Epitaxial BFO films (about 100 nm thick) were grown using laser-MBE in (111), (110) and (100) orientations, using carefully controlled single crystal SrTiO₃ substrates. A thin 50 nm layer of epitaxial SrRuO₃ was used as a bottom electrode for electrical contact purposes. Ferroelectric domains were imaged using piezoresponse force microscopy (PFM) as described in Zavaliche, F., et al., Multiferroic BiFeO₃ films: domain structure and polarization dynamics, Phase Transit. 79, 991-1017 (2006), incorporated by reference herein. Controlled ferroelectric domain patterns were written using PFM by applying a dc voltage to the probe tip. Local electrical conductivity was measured using high resolution conductive atomic force microscopy (c-AFM) by applying a bias voltage (below the polarization switching voltage) between the conductive AFM tip and the bottom electrode of the sample. The measurements were performed on a Digital Instruments Nanoscope-IV Multimode AFM equipped with a conductive-AFM application module (TUNA™). Commercially available nitrogen doped diamond coated Si-tips (NT-MDT) and Ti/Pt coated Si-tips (MikroMasch) were used. Current amplification settings of the c-AFM equipment of 1 V/pA and 10 V/pA at an applicable voltage range of +/−12 V were used. For a typical scan rate of 0.5 to 1.0 microns per second, the noise level was of the order of 50 fA at a bandwidth of 250 Hz. All data were acquired under ambient conditions and at room temperature and all such c-AFM measurements were performed within a few minutes after the domain wall was created by electrical switching.

100 nm thick epitaxial films were grown on (110) surfaces. The films exhibit a 2-variant ferroelectric domain structure in the as-grown state with domain sizes between 5-10 μm. On electrical switching at high field, all three variations of domain walls can be created. See Cruz, M. P., et al., Strain control of domain-wall stability in epitaxial BiFeO₃ (110) films, Phys. Rev. Lett. 99, 217601 (2007), incorporated by reference herein.

The RMS roughness of the films was measured to be about 0.5 nm with no observable surface features, before or after switching, corresponding to the conducting features. FIG. 1b shows an out-of-plane PFM image of a written domain pattern controlled to have all three domain wall types. The complicated domain shapes only occur when the large voltages required to stabilize all three domain wall variants are applied. The various domain wall types were determined using both out-of-plane (FIG. 1b) and in-plane (FIG. 1c) PFM images and are labeled accordingly. FIG. 1b is an out-of-plane PFM image of a written domain pattern in a monodomain BFO (110) film showing the out-of-plane polarization component of the domains to be either down, labeled as “D” (white), or up, labeled as “U” (black). FIG. 1c is an in-plane PFM image of a written domain pattern in a monodomain BFO (110) film showing all three types of domain walls, i.e. 71°, 109°, and 180°, as inferred from the combination of both out-of-plane and in-plane PFM images. In this image, both the out-of-plane (U or D) component as well as in-plane projection of the polarization direction (shown as an arrow) are also labeled. Conduction across the films was measured by a c-AFM trace. FIG. 1d shows the corresponding c-AFM trace for the images in FIGS. 1b and 1c, showing the occurrence of electrical conduction at 109° and 180° domain walls, and the absence of conduction at 71° domain walls. BFO films grown on (001)- and (111)-oriented substrates also consistently showed conduction at 109° and 180° domain walls; in no case did 71° domain walls show conduction within the resolution of the measurements.

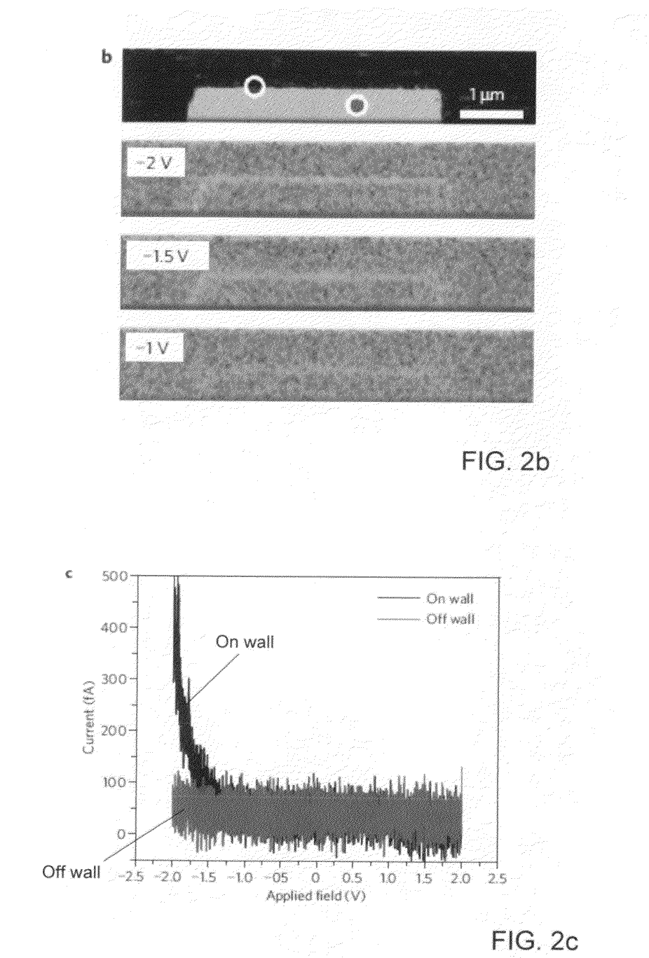

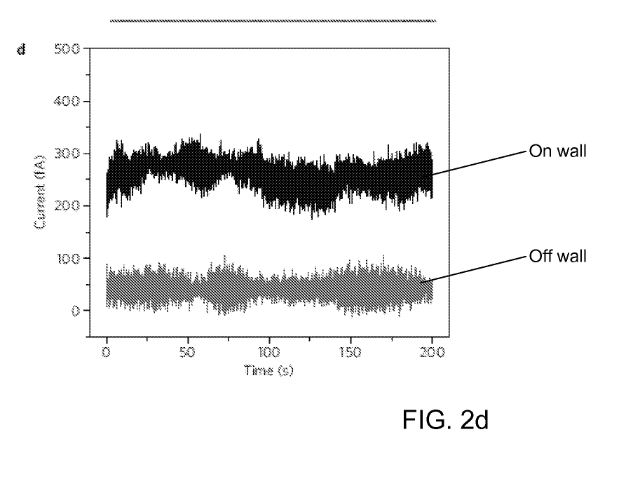

A schematic of the experimental setup used to perform c-AFM measurements on the (110)-oriented BFO films is shown in FIG. 2a. The spatial resolution of the technique is limited by the tip radius of about 20 nm. FIG. 2b (upper) shows a PFM image of two domains separated by a 180° domain wall. The corresponding c-AFM images (lower panels) show enhanced conduction at the domain wall for applied bias voltages of −1 to −2V. As shown in FIG. 2b, the trace is brightest at −2V and dimmest at −1V. FIG. 2c shows current-voltage (I-V) curves of the domain wall and off the domain wall. The on-wall curve shows a highest current level at −2V, decreasing to background level measured at the resistive domain. FIG. 2c and other current-voltage (IV) curves show resistive behavior within the domain and Schottky-like behavior suggesting activated conduction at the domain wall. IV measurements were repeated with a number of different c-AFM tip materials—including Pt and N-doped diamond—and found similar Schottky-like behavior with slightly shifted conduction onsets. Furthermore, the current is persistent over a time scale of at least 3 minutes, which is limited by the drift in the scanning system. FIG. 2d shows time dependence of the current both on the wall and off the wall at an applied sample bias of −2V. These time-dependent data indicate that the origin of this current is not displacement of domain walls. Ultra-high vacuum based c-AFM measurements were used to further probe the nature of conduction and IV characteristics of the conducting domain walls—including the observation of enhanced current values.

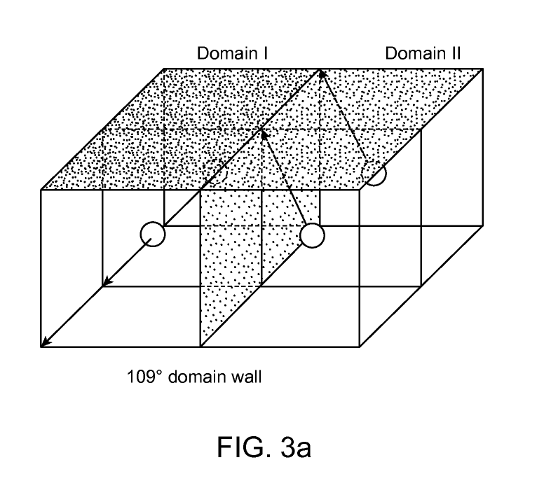

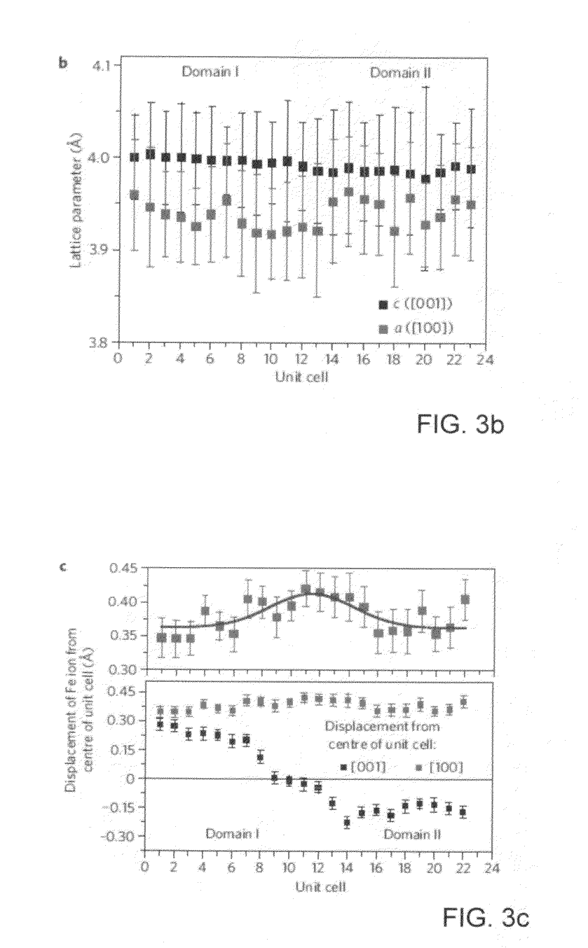

To understand the observed electrical conductivity, a combined transmission electron microscopy (TEM) and density functional theory (DFT) study of the domain wall structure and properties was performed. The 109° domain wall (shown schematically in FIG. 3a) was studied because conduction at 71° domain walls was not obtained and because imaging of 180° domain walls with high resolution-TEM (HRTEM) presents practical problems in terms of locating the wall. (001)-oriented samples were used for the TEM analysis, because density of 109° domain walls during growth can easily be controlled for this orientation. TEM images were acquired using the exit wave reconstruction approach to eliminate the effects of objective lens spherical aberrations; such images can be directly interpreted in terms of the projection of the atomic columns. Analysis of the images was used to determine the lattice parameter in the plane of the film (a) ([100]) and the lattice parameter out-of-the-plane of the film (c) ([001]) FIG. 3b shows the extracted a and c lattice parameters for each unit cell across the domain wall (with the lower values being the a lattice parameter and the higher values the c lattice parameter.) The in-plane lattice parameter is slightly smaller and the out-of-plane lattice parameter larger than the values in bulk BFO (3.96 Å) due to the strain inherent in the epitaxial films. In addition, both the in-plane and out-of-plane film lattice parameters were found to be are unchanged in the vicinity of the domain wall. The relative displacement of the Fe-ion with respect to the Bi-sublattice ws extracted and resolved into components parallel ([001]) and perpendicular ([100]) to the domain wall by quantitative analysis of the HRTEM data; this distance is representative of the local polarization. FIG. 3c shows the extracted Fe-ion displacement relative to the Bi lattice for each unit cell across the domain wall. The close-up (upper panel) reveals an increase in the component of polarization perpendicular to the domain wall. The component of the displacement parallel to the domain wall (along [001]) decreases in magnitude to zero at the center of the domain wall before changing to the same magnitude (but opposite sign) on the other side of the wall, reflecting the change in polarization orientation of the domain. Interestingly, the perpendicular displacement component (along [100]) shows a small increase at the domain wall, as shown in the upper panel. As discussed further below, this indicates that the perpendicular displacement component give rise to the electrostatic potential. Again only minor variation in lattice parameters was observed across the domain wall. In this case a similar step in Fe-ion displacement is observed parallel to the domain wall, though a step in the perpendicular component across the wall was not resolved.

To investigate the influence of these structural changes on the electronic properties, a density functional study of the structure and electronic properties was performed for all three ferroelectric domain wall variants. Full structural optimizations of the ionic positions with the lattice parameters fixed to their experimental bulk values were performed; in particular the oxygen polyhedral rotations around the polar axis, which have a profound effect on both the magnetic and electronic properties and cannot be easily extracted from the HRTEM data, were accurately calculated. Since the sense of the oxygen rotations around the polar axis is independent of the direction of polarization along the axis two scenarios were studied: first the sense of rotation was initialized to be continuous across the domain boundary and second the rotation sense was changed when the polarization direction changed. It was found that domain walls with continuous oxygen rotations are considerably lower in energy, since this avoids formation of an antiphase boundary associated with the octahedral rotations. In addition, domain wall configurations centered at both the Bi—O and Fe—O plane were investigated and it was found that the Bi—O walls were slightly lower in energy, confirming the findings of the HRTEM analysis. The lowest energy calculated configuration for the 109° domain wall had a domain wall energy of 206 mJ/m².

To confirm that the calculated structure is consistent with the TEM data, the layer-by-layer polarization, defined as the sum over the bulk Born effective charges multiplied by the displacements of the ions from their centrosymmetric reference positions in each layer, was analyzed. The local polarization in the middle of the domain is close to the value calculated for bulk BFO using the same computational and lattice parameters (−0.93 μC/cm²), confirming that the supercell is large enough to capture the essential physics. Consistent with the TEM analysis, an abrupt change in the parallel polarization component across the domain wall and a small change in the normal component at the domain wall was found.

The calculations indicate that this small change in the normal component of the polarization across the 109° domain wall leads to a step in the electrostatic potential (planar and macroscopically averaged) of 0.15 eV across the domain wall (Table I); a similar step was computed and explained previously across 90° domain walls in PbTiO₃. Such a potential step should enhance the electrical conductivity by causing any free carriers in the material to accumulate at the domain wall to screen the polarization discontinuity. The calculations for the 180° domain wall also yield a variation in the normal component of the polarization, and a corresponding potential step of 0.18 eV (Table I). The normal component results from the polarization rotating towards successive adjacent corners of the perovskite unit cell, through a 71° and than a 109° change in the polarization direction before reaching the reversed polarization. This behavior is in striking contrast to the 180° polarization reversal in tetragonal ferroelectrics where the polarization changes in only one direction within the wall plane and no normal component occurs. The 71° wall, however, has a negligible change in the perpendicular component, again consistent with the TEM data, and therefore a negligible potential step (Table I).

TABLE 1
Electronic structure at ferroelectric domain walls

| | Calculated electrostatic | Calculated change in |
|---|---|---|
| Domain wall type (°) | potential step (eV) | bandgap (eV) |
| 71 | 0.02 | 0.05 |
| 109 | 0.15 | 0.10 |
| 180 | 0.18 | 0.20 |

The electronic properties of the structurally optimized domain walls, in particular by comparing the layer-by-layer densities of states in the domain wall and mid-domain regions, were also calculated. Within the central region of the domain, it was found, as expected, that the local density of states resembles that of bulk BFO, and the local Kohn-Sham band gap is equal to the value of 1.3 eV obtained for bulk BFO with the same choice of U and J values. (It should be noted that while the DFT Kohn-Sham band gaps do not correspond to experimental band gaps, changes in DFT gaps caused by changes in bandwidth as a consequence of small changes in structure for the same DFT implementation are qualitatively meaningful.) As the domain wall is approached, changes in the structure indeed cause changes in the band width and the positions of the band edges. This leads in the 109°) (180°) case to a 0.1 eV (0.2 eV) reduction in the band gap in the domain wall layer from the mid-domain calculated value of 1.3 eV (Table I). For activated conduction at room temperature, such a change in band gap, or in band edge offset relative to the Fermi energy of the tip, should lead to considerable changes in conductivity. Consistent with its absence of conduction, the reduction in band gap in the 71° case is smaller (0.05 eV) (Table I). Interestingly, the magnitude of the band gap reduction is sensitive to the details of the lattice parameters used in the calculation; when the lattice parameters were allowed to relax away from the constrained bulk values, the changes in the band gap are around 50% smaller. This suggests that band structure changes at domain walls might be tunable by epitaxial strain.

Without being bound by any particular theory, the conductivity measurements, TEM analysis, and DFT calculations suggest two mechanisms which may combine to yield the observed conductivity at the 109° and 180° domain walls: (1) an increased carrier density as a consequence of the electrostatic potential step at the wall and (2) a decrease in the band gap within the wall and corresponding reduction in band offset with the c-AFM tip. Both factors are the result of structural changes at the wall.

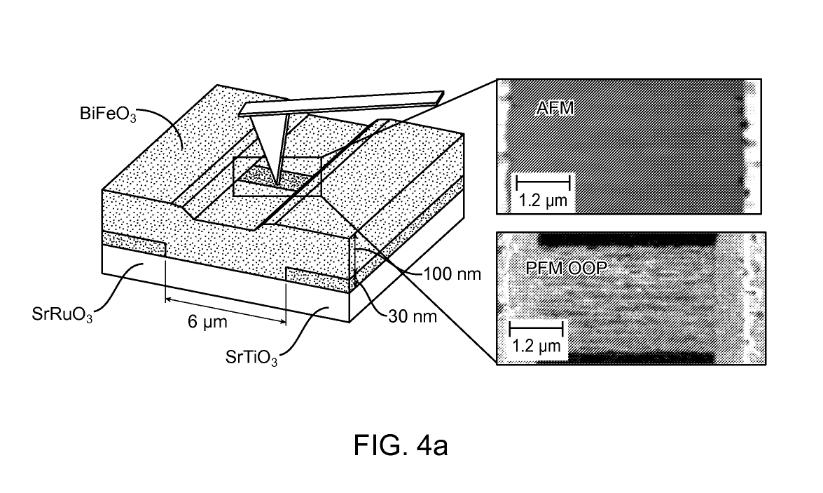

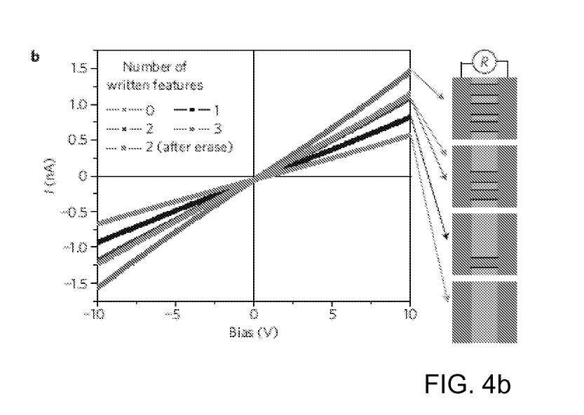

The potential of these conducting domain walls for device applications is illustrated in FIG. 4a and FIG. 4b. A simple device structure including in-plane electrodes of SRO separated by a 6 μm spacing (FIG. 4a) was constructed to measure the IV characteristics of BFO films and domain walls macroscopically. The SRO contacts provide nearly Ohmic contacts with the BFO films, allowing further insight into the conduction of the walls in the gap, without any interference from the AFM tip during the measurement process. Monodomain (110)-oriented BFO films were grown on top of the SRO in-plane device structures on STO (110) substrates. Conducting domain wall features (here are shown 180° domain walls, FIG. 4a right) that connect the two in-plane electrodes were written using PFM. Again, no morphological surface features were observed that correspond to the written domain pattern. I-V measurements (FIG. 4b) reveal a step-like increase in the measured current between the two in-plane electrodes upon addition of a controlled number of conducting domain walls. The steps in conduction are essentially equidistant, increase proportionally to the total number of domain walls written, and show completely reversible behavior upon erasing a given feature. I-V curves for 0, 1, 2, and 3 domain features are shown in FIG. 4b. Note there are two domain walls per written domain feature. Such material functionality has potential application in both logic and memory applications as the wall location (and hence electronic conduction) can be precisely controlled on the nanoscale. This demonstrates a rewritable, multi-configuration device setup that utilizes nanoscale conductive channels (i.e., conducting domain walls). Based on a simple sheet resistance model, the resistivity of a single domain wall in the BFO film is on the order of 1-10 Ω·m which is between 5-6 orders of magnitude lower than for bulk BFO. As discussed below, the resistivity can be lowered further by chemical and physical manipulation.

The results show that ferroelectric domain walls in multiferroic BFO exhibit unusual local electronic transport behavior that is quite different from that in the bulk of the material or in conventional ferroelectrics. The conductivity is consistent with the observed changes in structure at the domain wall and can be activated and controlled on the scale of the domain wall width—about 2 nm in BFO. This shows that domain walls are discrete functional entities which may be addressed and sensed and may be used in novel nanoelectronic applications, as described further below. Further details of the above-described experimental set up and results of conduction at domain walls in oxide multiferroics may be found in Seidel, J., et al., Conduction at domain walls in oxide multiferroics, Nature Materials, 8, 229-234 (2009), incorporated by reference herein.

While the discussion herein refers chiefly to multiferroics in general and to BFO in particular, the thin film may be any material that includes conducting domain walls and may include any material that has at least one order parameter and that form domains and domain walls. Examples of ferroelectric materials, for example, are provided below.

In addition to BFO, characteristics of materials that exhibit conducting walls may include possessing a relatively low band gap (e.g., less than about 3.5 eV or less than about 3.0 eV; BFO band gap is about 2.67 eV), are relatively ferroelectric and may have relatively strong electron correlation. Examples of materials include perovskite structures (ABO₃). These include bismuth-based perovskites such as BiFeO₃, BiMnO₃, BiCrO₃, BiCoO₃ and BiNiO₃; lead-based perovskites such as PbFeO₃, PbTiO₃, PZT (Pb[ZrₓTi₁₋ₓ]O₃ 0<x<1); lead magnesium niobate-lead titanate (PMN-PT), and PbMoO₄-related compounds; BaTiO₃ and related derivatives; Bi-layered compounds such as Bi₄Ti₃O₁₂ and related derivatives; and GdMoO₄. Various crystal structures may be used; for example, while rhombohedral BFO is described above, in certain embodiments, tetragonal or other forms of BFO or other materials may be used.

According to various embodiments, the material compound may be a d⁰ compound (i.e., a compound with a formal valence state of 0) or a non-d⁰ compound. In certain embodiments, non-d⁰ may be more likely to exhibit conducting walls. Multiferroic organic materials (e.g., polyvinylidene-fluoride or PVDF composites) may also exhibit conducting domain walls.

In certain embodiments, the materials may be manipulated to increase or decrease the conductivity of the domain walls. In certain embodiments, the A or B sites of the ABO₃ materials are doped. For example, the A site may be doped with aliovalent dopants such as Ca, Pb, Ba, Sr, K and Na and isovalent dopants such as rare earth metals (e.g., La). The B-site may be doped with isovalent dopants such all transition metals (e.g., Co and Ni). Examples of doped compounds include Ca—BiFeO₃ and La—BiFeO₃. Extent of doping may be from 0-50% replacement at the A and/or B site.

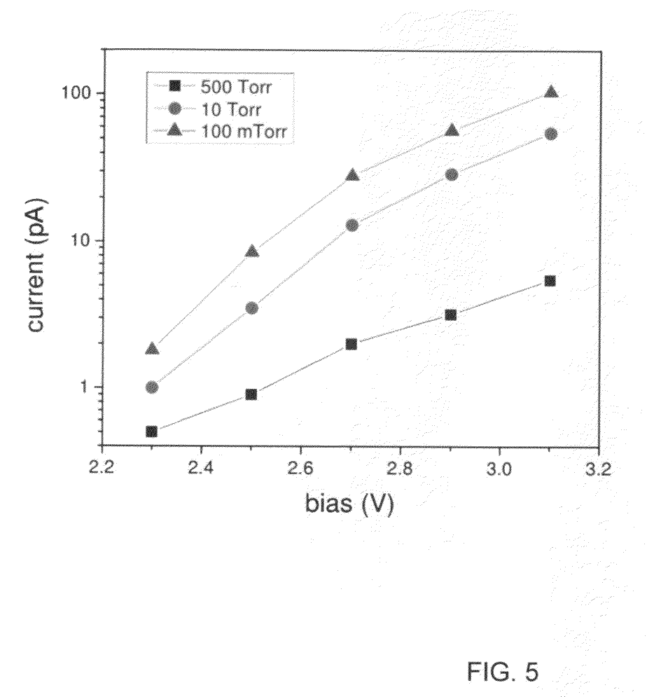

It has been found that conductivity may be increased by reducing the oxygen content in the ABO₃ film in certain embodiments. BFO films were formed at high temperature and cooled to room temperature in an oxygen environment at different pressures, with pressure corresponding to eventual oxygen content. FIG. 5 shows IV curves for 100 mTorr, 10 Ton and 500 Torr. As shown, the conductivity is the lowest for 500 Ton; and highest for 100 mTorr.

As indicated above, the high sensitivity of the conductive response to unit cell size indicates that the conductivity may be manipulated by applying a strain to the multiferroic film. Film strain may be controlled by selecting the substrate on which the film is formed to increase or decrease lattice mismatch between the substrate and the film. Manipulating the crystalline structure (e.g., tetragonal rather than rhombohedral) may also tune the band gap.

The above techniques may be used to achieve nano-ampere conductivities, and possibly higher conductivities. Current densities as high as about 5×10⁸ A/m² or higher are achievable according to various embodiments. In certain embodiments, the above techniques may be used to form conductive domain walls in material that do not otherwise exhibit them. For example, rhombohedral ferroelectric PZT has been shown not to exhibit conductive domain walls. One possible explanation is that the band gap is >3.5 eV; while the structural differences at the wall diminish the band gap, it may not be enough to permit conduction at room temperature. However, manipulating PZT as discussed above may allow conductive walls to form.

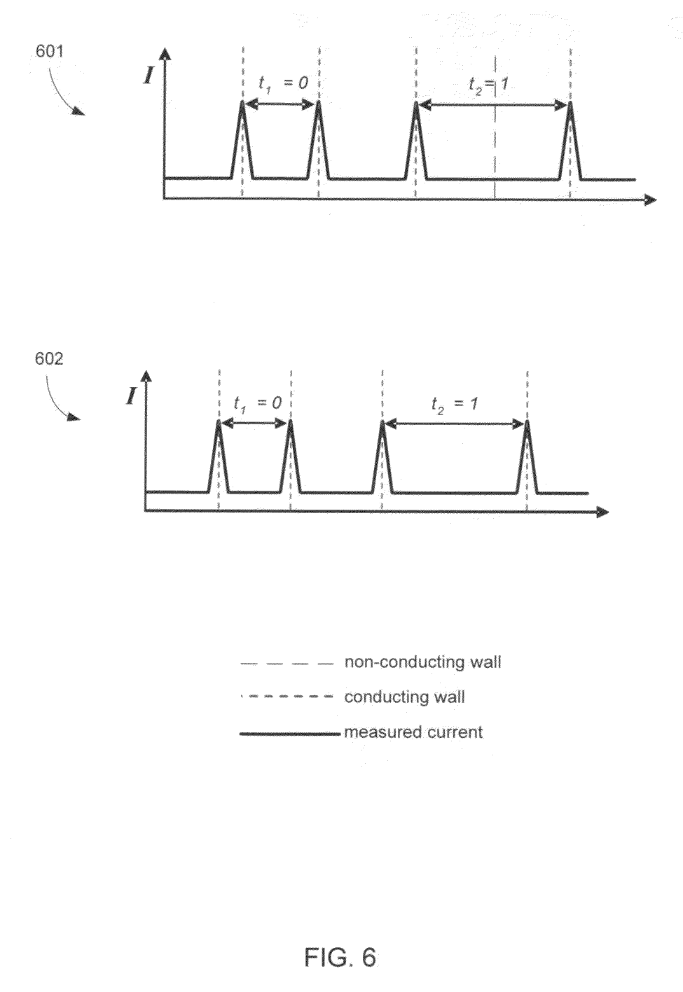

According to certain embodiments, patterned media are provided in which the media includes a multiferroic film including conducting domain walls, with the conducting domain walls arranged to form the pattern. Data is stored in a set of domain walls. The presence or absence of a conducting domain wall and/or the spatial distance between conducting domain walls may be used to store data. FIG. 6 illustrate examples in which a pattern of conducting and non-conducting domain walls are formed in a multiferroic film using the spacing of the domain walls in the film and controlling the type of domain wall (conducting or non-conducting) written. At 601, FIG. 6 shows a sample current vs. time curve for a BFO (or other multiferroic film exhibiting conducting and non-conducting walls) and a bottom electrode layer such as SRO. In the example shown, the intrinsic spacing of the domain walls is used to write binary data: an “0” is encoded by writing two conductive domain walls (e.g., 180° walls for BFO) next to each other separated by the intrinsic spacing between domain walls. A “1” is encoded by writing two conducting domain walls separated by a single non-conducting domain wall (e.g., a 71° wall for BFO). In an alternate embodiment, a “1” may be encoded by writing two conducting walls separated by a single domain larger than that separating the conducting walls encoding a “0.” A sample current vs. time curve for this embodiment is shown at 602.

In certain embodiments of the memory described herein, the read and write processes are performed with electronic signals only. A voltage V_{R} required to read the media is lower than the voltage V_{W} that writes the features. Higher order memory states may be formed in certain embodiments. In the embodiment depicted in FIG. 6, there is no difference in conductivity at the domain walls. However, in alternative embodiments, there may be a measurable difference in conductivity of conducting domain wall depending on the number of adjacent conducting domain walls and/or the distance to other conducting, domain walls. In certain embodiments, the film includes magnetic and non-magnetic conducting walls. The addition of measurable differences in conductivity at different domain walls and/or the presence of magnetism at the domain walls allow a 4-state or higher order memory or logic system.

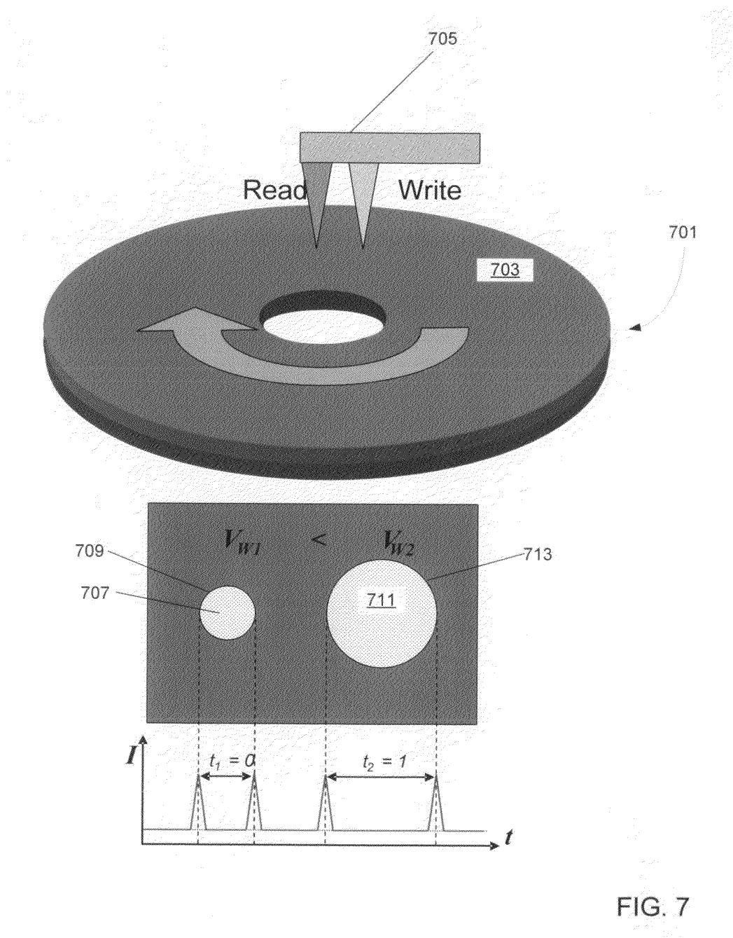

In certain embodiments, circular data bits are written. FIG. 7 shows an example of a patterned media disk 701, including a multiferroic thin film 703. A read/write head 705 is positioned above the disk. A low-write voltage (V_{W1}) is used to write a small diameter circular domain 707 and conductive domain wall 709. A read voltage V_{R} lower than V_{W1} is used to read the data; the small diameter circle short has a read time t₁. A high-write voltage (V_{W2}) writes a larger diameter domain 711 and conductive domain wall 713, and a long read time t₂, giving “0” and “1” bits. An example current vs. time curve for a “0” and “1” bits is also shown. In certain embodiments, the duration of the write voltage may be used to create two different sizes of bits in addition to voltage magnitude, with short pulses giving small bits and long pulses giving large bits. In certain embodiments, similar to classic magnetic hard drives, the media spins allowing the stationary read/write head to contact the disk surface.

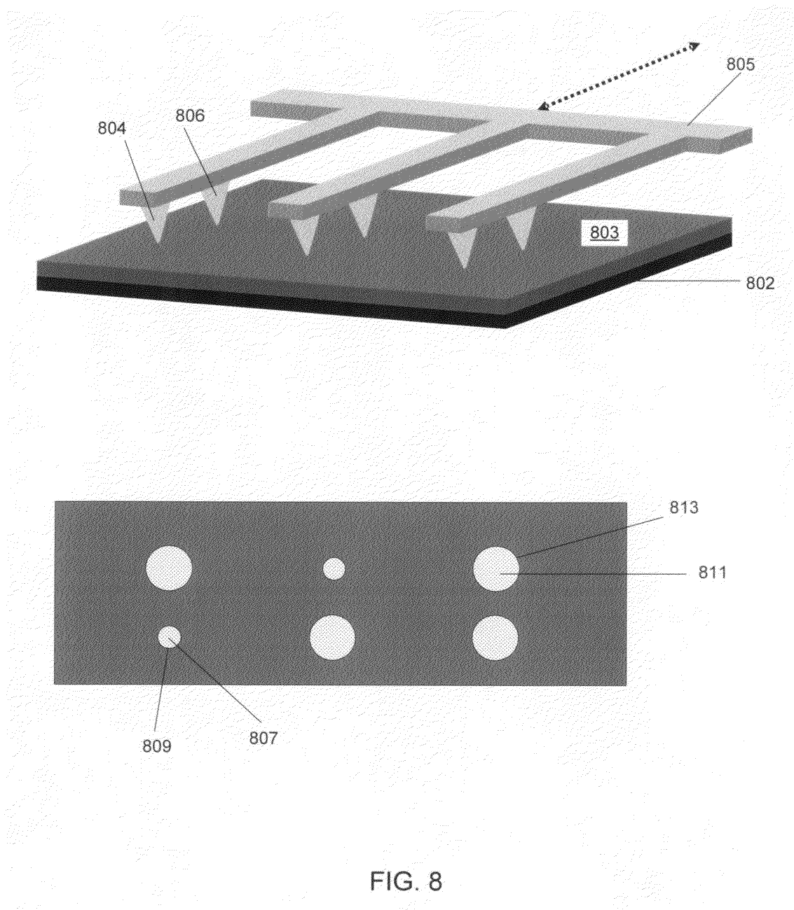

In other embodiments, the patterned media is configured to be read/written by massively parallel read/write heads. An example is depicted in FIG. 8, which shows patterned media including substrate 802 and multiferroic film 803. Substrate 802 may include a layer on which the multiferroic film is grown as well as one or more additional layers for packaging or handling. The media is addressed by parallel read/write head mechanism 805 including write heads 804 and read heads 806. As with the example in FIG. 7, a low-write voltage (V_{W1}) is used to write a small diameter circular domain 807 and conductive domain wall 809. A read voltage V_{R} lower than V_{W1} is used to read the data; the small diameter circle short has a read time t₁. A high-write voltage (V_{W2}) writes a larger diameter domain 811 and conductive domain wall 813, and a long read time, giving “0” and “1” bits.

These read/write mechanisms may be scanning probes or other mechanisms configured to write and read the conducting domain walls as described below. As with the pattern media depicted in FIG. 7, the pattern includes conductive domain walls, with the read time and bit value determined by the spatial distance between conductive domain wall reads, e.g., the diameter of a circle in the examples in FIGS. 7 and 8.

The examples in FIGS. 7 and 8 envision a read/write head or patterned media moving via mechanical apparatus, e.g., a disk spinning in FIG. 7 or read/write heads moving in FIG. 8. In alternate embodiments, the film and read/write elements may be stationary with voltage pulses used to drive the conducting domain wall sequences past the elements. This is similar to magnetic “racetrack memory” systems described for example in U.S. Pat. Nos. 4,360,894 and 7,551,469, both incorporated by reference herein, with several important distinctions. First, the pattern is at nanoscale dimensions; conductive domain walls are on the order of ones of nanometers with feature density (dictated by domain size) as low as about 10 nm-50 nm, e.g., 25-50 nm. Magnetic domain walls are typically on the order of 100s of nanometers wide and separated by a minimum of a similar length scale. Second, the domains and conductive domain walls may be moved by electric fields. (See e.g., Shafer, P., et al. Planar electrode piezoelectric force microscopy to study electricpolarization switching in BiFeO₃, Applied Physics Letters 90, 202909 (2007) and Y. Chu, Y., et al., Electric-field control of local ferromagnetism using a magnetoelectric multiferroic, Nature Materials 8, 478-482 (2008), both of which are incorporated by reference herein.) This allows a voltage pulse, rather than a current pulse, to be used to move the conducting domain walls. This eliminates the need for high current pulses. In alternative embodiments, read-only elements may be provided to read pre-existing states associated with various conductive domain wall patterns.

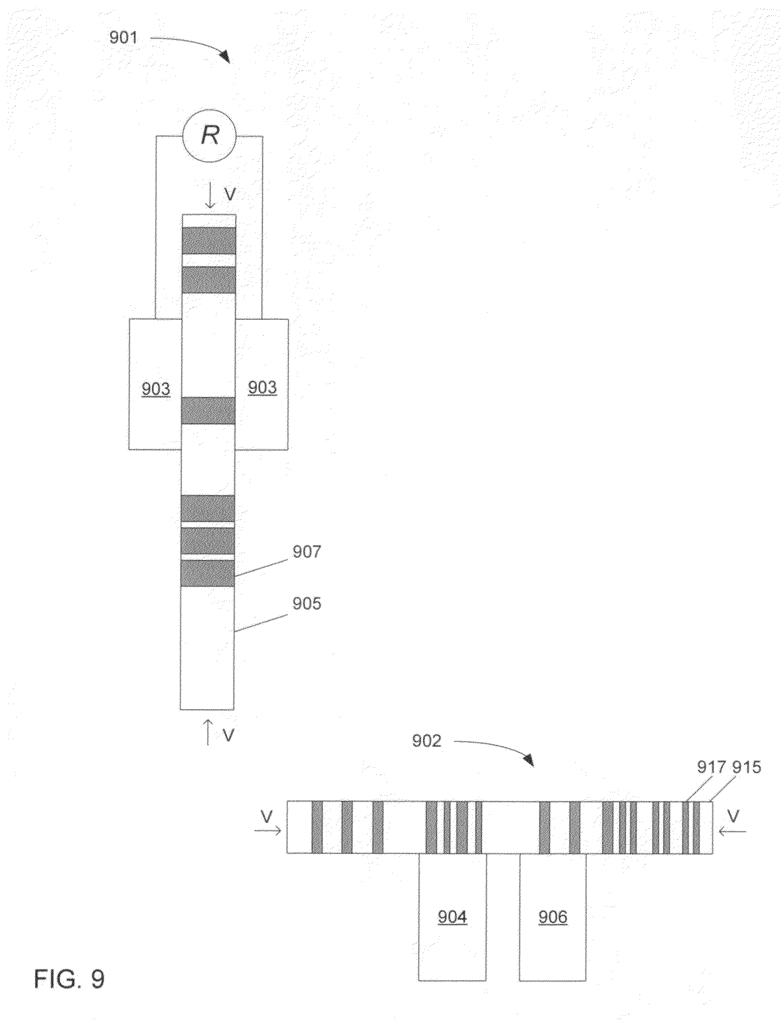

In another example of a device, conducting domain walls are written to span a channel between two read electrodes. A simple example is shown in FIG. 4, above. In a related example, a multiferroic film having conducting domain wall patterns may extend past the electrodes, such that only the conducting walls between the electrodes are read. A voltage pulse may be used to move different conductive domain wall patterns between the read electrodes. FIG. 9 shows schematics of devices in which applied electric fields are used to move domain walls. At 901, multiferroic film 905 including domain features 907 is shown. A portion of multiferroic film 905 including a domain wall pattern is between read electrodes 903. These electrodes may be any type of conductive contacts. The film 905 and electrodes 903 are stationary with domain walls moved by voltage pulses as indicated by the arrows at either end of the film. Only the domain wall pattern between electrodes 903 is read. At 902, multiferroic film 915 including domain features 917. Applied electric fields are also used in this example to move domain features 917 and conductive domain walls pass write element 904 and read element 906. In addition to memory and logic devices, strain sensing applications are provided. For example, resistivity of a conducting domain wall may be measured as the multiferroic film is strained. Straining or bending the multiferroic will result in motion of the domain walls and changes in the domain size. If this motion occurs under a contact position, strain, or motion can be detected using such a device.

Examples of substrates on which the epitaxial multiferroic thin films described herein may be grown on include, but are not limited to, YAlO₃, LaSrAlO₄, LaAlO₃, LaSrGaO₄, NdGaO₃, (LaAlO3)_{0.3}—(Sr2AlTaO6)_{0.7} (LSAT), LaGaO₃, SrTiO₃, DyScO₃, GdScO₃, SmScO₃, KTaO₃, NdScO₃, Si, SrTiO₃/Si, GaN, GaAs, GaAlAs, AlGaN, glass and metal coated glasses.

Examples of oxide bottom electrodes that may be used in the epitaxial growth of films include, but are not limited, to SrRuO₃, La₁₋ₓSrMnO₃ (various values of x), La₁₋ₓSrₓCoO₃ (various values of x), La₁₋ₓCaₓMnO₃ (various values of x), LaNiO₃, SrVO₃, CaVO₃, RuOₓ, In-doped SnOₓ (indium doped tin oxide or ITO), Y—Ba—Cu—O (such as, but not limited to, YBa₂Cu₃O₇) and Nb-doped SrTiO₃. Other bottom electrodes such as Pt, Pd or other metals, or doped semiconductors such as doped-Si, may be used to grow non-epitaxial films. In certain embodiments, electrodes may be placed in electrical contact with the conducting domain walls after growth, e.g., on the opposite sides of a domain wall. Any type of electrode may be used. If a substrate is conducting, it may also be used as a bottom electrode in embodiments in which bottom electrodes are used.

The multiferroic films grown may be epitaxial or non-epitaxial. Intrinsic domain size correlates to film thickness, with film thicknesses typically ranging from about 25 nm-1000 nm. Domain size (which determines conducting wall feature density) may be as low as about 10 nm-50 nm, and may be arbitrarily large. Allowable pattern density, which may be defined as the minimum distance between conducting wall features (e.g., in the case of circular domains, the diameter of the circle, in the case of the cross-channel domains in FIG. 4, the width of the domain, etc.) may be as low as about 10 nm, 25 nm, 30 nm, 40 nm, 50 nm, 60 nm, 75 nm, 80 nm, 90 nm, 100 nm, etc., according to various embodiments. For scanning probe read mechanisms, the pattern density is limited by the width of the scanning probe tip. Width of the conducting walls depends on the material, though is typically 2-3 nm.

As grown, the multiferroic films can be controlled to be monodomain (i.e., possessing no domain walls) or controlled to possess a wide range of densities and types of domain walls. Controlled writing of domains is performed by applying a switching voltage to the film, with placement of the applied voltage and magnitude and/or duration of the applied voltage determining the position and size of the domain, the position and spacing of the domain walls and type of domain wall. In certain embodiments, controlled switching is performed using a scanning probe. Controlled switching using PFM is described in Cruz et al., Cruz, M. P., et al., Strain control of domain-wall stability in epitaxial BiFeO₃ (110) films, Phys. Rev. Lett. 99, 217601 (2007) and Zavaliche, F., et al., Multiferroic BiFeO₃ films: domain structure and polarization dynamics, Phase Transit. 79, 991-1017 (2006), both incorporated by reference herein.

Reading the nanoscale patterns may be performed by applying a voltage across the material at the point of interest and detecting or measuring current. As indicated above, the read voltage is lower than the write voltage(s) to avoid unwanted switching. In certain embodiments, reading is performed using a scanning probe mechanism such as conducting atomic force microscopy (c-AFM) mechanism described above. In other embodiments, reading a pattern may be performed by applying a voltage across stationary electrodes and detecting current. Features may be erased through a similar process. Application of the opposite voltage will switch the domain back to the original state. This can be performed in the same manner as writing the domain.

Another aspect relates to photovoltaic devices including ferroelectric materials. In certain embodiments, this involves a previously unrecognized mechanism of charge separation and photovoltage generation that occurs exclusively at nanometer-scale ferroelectric domain walls. In certain embodiments, the devices produce above bandgap voltages. In conventional solid-state photovoltaics, electron-hole pairs are created by light absorption in a semiconductor and separated by the electric field spanning a micrometer-thick depletion region. The maximum voltage these devices can produce is equal to the semiconductor electronic bandgap. The conversion process of light energy to electrical energy in photovoltaic devices relies on some form of built-in asymmetry that leads to the separation of electrons and holes. The fundamental physics behind this effect (for example, in silicon-based cells) is charge separation using the potential developed at a p-n junction, or heterojunction. Anomalous photovoltaic effects in polar materials have been found to arise from two mechanisms: (i) granularity and (ii) the inherent non-centrosymmetry in the bulk material, that is, the absence of an inversion centre of symmetry. The former mechanism inevitably suffers from the granular interface being poorly controlled, and the latter is typically seen in wide-bandgap semiconductors (Eg>2.5 eV), which absorb very little of the visible spectrum.

In certain embodiments, the photovoltaic devices described herein rely on a new mechanism of charge separation and photovoltage generation that occurs exclusively at nanometer-scale ferroelectric domain walls in ferroelectric materials. In certain embodiments and in contrast to semiconductor-based photovoltaics, the photovoltages of the devices described herein are significantly higher than the electronic bandgap.

Photovoltaic activity in multiferroic bismuth ferrite is described below; however the invention is not so limited and includes other multiferroic and ferroelectric materials having domain walls. The rhombohedrally distorted perovskite structure of BFO leads to eight ferroelectric polarization directions along the pseudocubic 111-directions, corresponding to four structural variants. The possible domain pattern formation in (001)-oriented epitaxial rhombohedral perovskite ferroelectric films and their control has been described in various references. The notation set used in Streiffer, S. K. et al. Domain patterns in epitaxial rhombohedral ferroelectric films. I. Geometry and experiments. J. Appl. Phys. 83, 2742-2753 (1998), incorporated by reference herein, is used herein. Domain walls in such materials are typically about 1-2 nm wide. BFO has a direct bandgap of about 2.67 eV (about 465 nm) and has been shown to display a conventional photovoltaic effect (open-circuit voltage V_{OC}<<E_{g}) and photoconductivity. See, Basu, S. R. et al. Photoconductivity in BiFeO3 thin films. Appl. Phys. Lett. 92, 091905 (2008) and Choi, T., et al. Switchable ferroelectric diode and photovoltaic effect in BiFeO3. Science 324, 63-66 (2009), incorporated by reference herein.

In certain embodiments, the ferroelectric thin films include ordered arrays of a domain walls. As described further below, the domain walls are approximately evenly spaced in certain embodiments, though the spacing may also be non-uniform in certain embodiments.

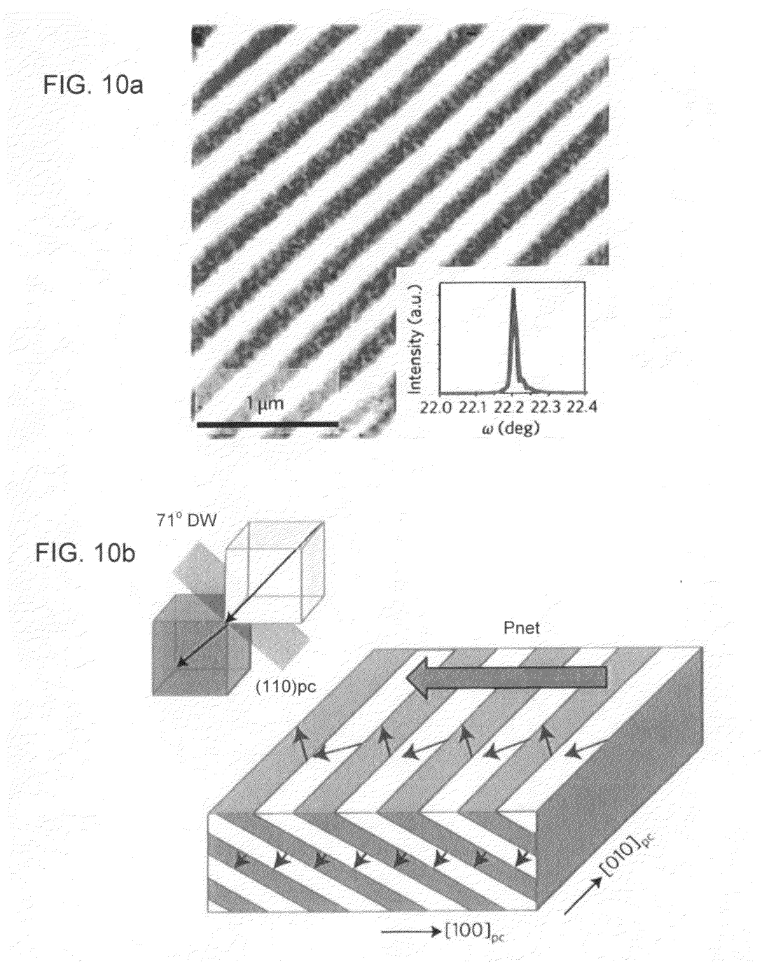

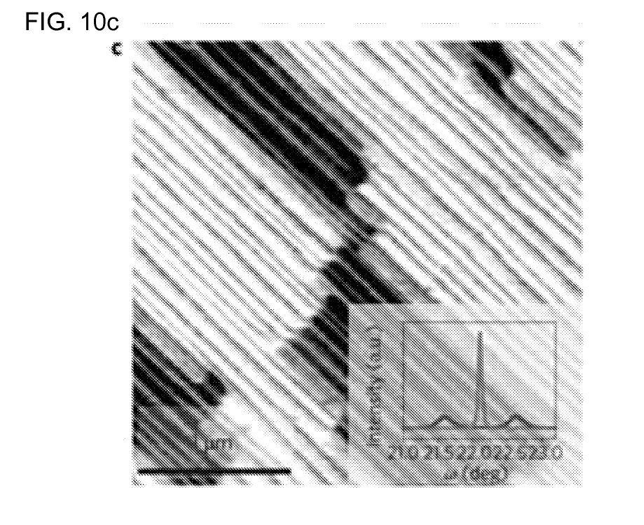

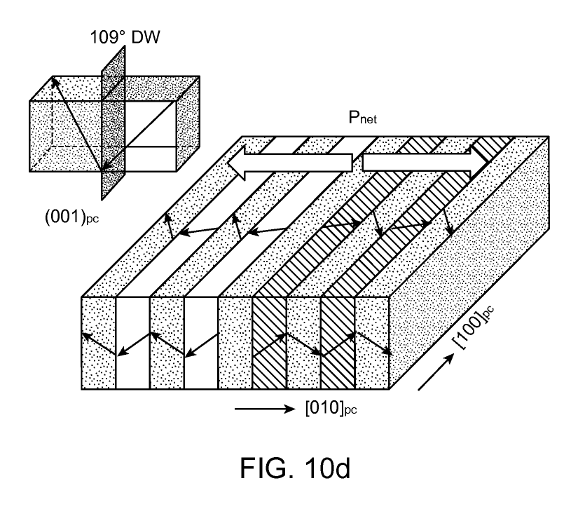

An ordered array of 71° domain walls created with a careful heteroepitaxial growth process are depicted in FIGS. 10a and 10b: a PFM image in FIG. 10a and a schematic depiction in FIG. 10b. An ordered array of 109° domain walls with two in-plane variants are depicted in FIGS. 10c and 10d: a PFM image in FIG. 10c and a schematic depiction in FIG. 10d). The insets of FIGS. 10a and 10c show the corresponding X-ray rocking curves, along two orthogonal crystal axes, demonstrating the high quality of the films. The various arrows in FIGS. 10b and 10d map out the different components of polarization (both in-plane and out-of-plane) as well as the net polarization direction (large arrow) in the samples. Samples are found to have net polarization in the plane of the film. As indicated, X-ray diffraction studies (insets of FIGS. 10a and 10c) confirm the presence of these two different types of domain wall. See Chu, Y.-H. et al. Nanoscale control of domain architectures in BiFeO₃ thin films. Nano Lett. 9, 1726-1730 (2009), incorporated by reference herein.

Additional X-ray diffraction reciprocal-space-mapping studies reveal the high quality of these ordered stripe domains. In both cases, there is a net polarization aligned in the plane of the film, that is, perpendicular to the projection of the domain wall plane on the (001) film surface (See FIGS. 10b and 10d). Transmission electron microscopy (TEM) images of the two different domain structures show that the 71° domain walls lie along 101-type planes, whereas the 109° domain walls lie along 100-type planes, consistent with theoretical predictions. Detailed analyses of the atomic structure at these domain walls reveal a wall width of about 1-2 nm, consistent with previous work.

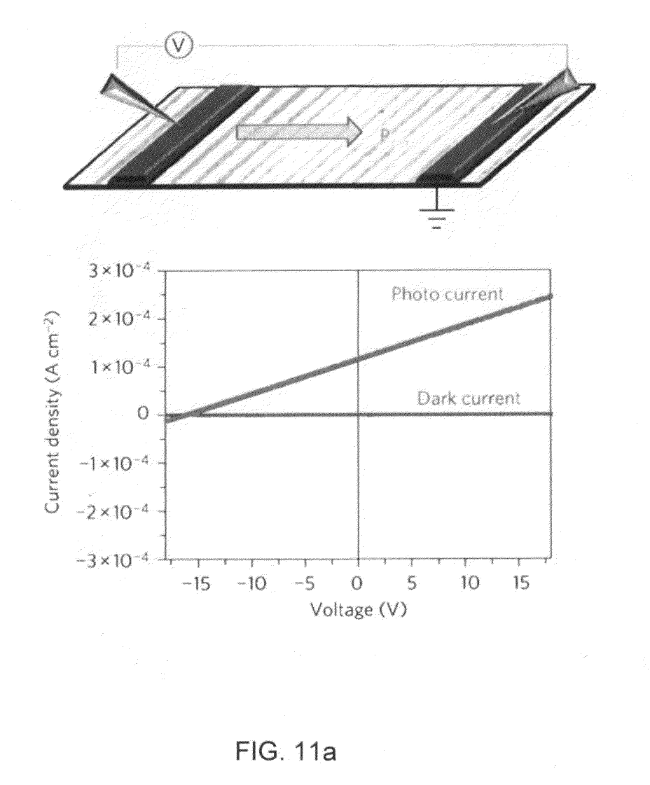

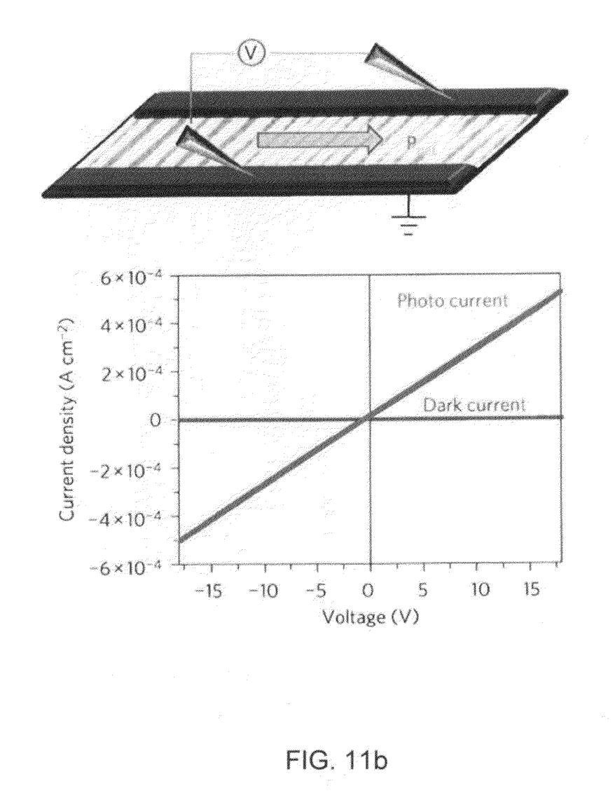

Test structures, based on symmetric platinum top electrodes with a length of 500 μm and an inter-electrode distance of 200 μm, were fabricated on top of 100-nm-thick films by photolithography in two geometries: electrodes for electric transport measurements (i) perpendicular (DW_{⊥}) and (ii) parallel (DW_{∥}) to the domain walls. Current-voltage (I-V) characteristics of samples in the two geometries, with ordered arrays of 71° domain walls, were measured under saturation illumination on the same film in both dark- and white-light illumination (285 mW cm⁻²) and reveal strikingly different photovoltaic behaviors. FIG. 11a depicts a schematic of the perpendicular device geometry for the DW_{⊥} geometry, and the corresponding I-V measurement; FIG. 11b depicts a schematic of the parallel device geometry for the DW_{∥} geometry, and the corresponding I-V measurement. In the DW_{⊥} direction, a large photo induced V_{OC} of 16 V was measured, with in-plane short-circuit current density J_{sc} approximately equal to 1.2×10⁻⁴ A cm². In contrast, dark and light I-V curves measured in the DW_{∥} direction exhibit a significant photoconductivity, but no photo induced V_{OC}.

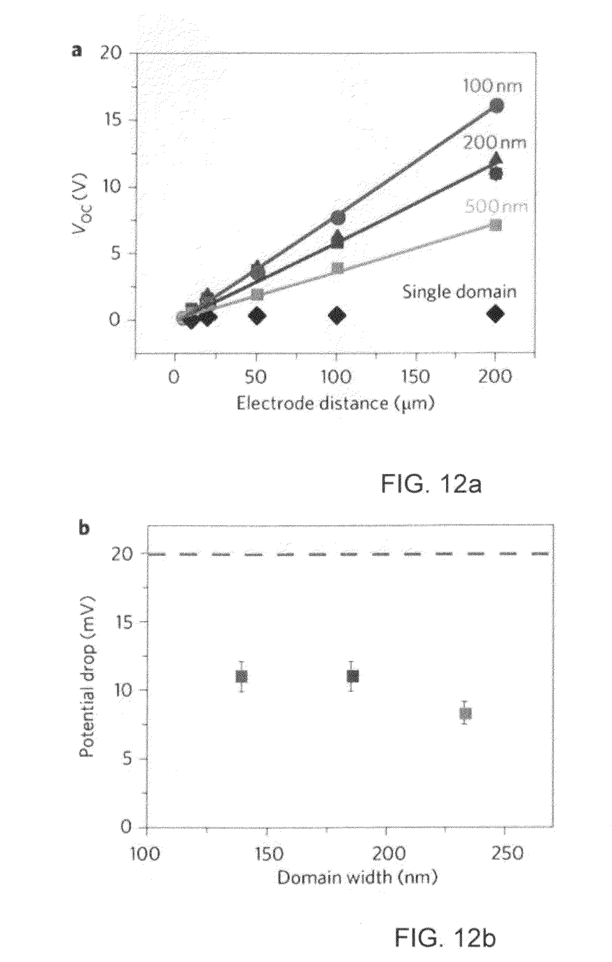

FIG. 12a is a plot showing V_{OC} as a function of electrode spacing for four different samples: 71° domain wall samples with thicknesses of 100 nm, 200 nm and 500 nm, as well as a monodomain BFO film having no domain walls. The plot shows a clear correlation between the number of domain walls and the magnitude of V_{OC}. The photo induced voltages increase linearly in magnitude as the electrode spacing is increased. A single domain sample (that is, with no domain walls between the platinum contacts) show negligible levels of photovoltage, which rules out a ‘bulk’ photovoltaic effect arising from non-centrosymmetry. In turn, this strongly suggests the prominent role of domain walls in creating the anomalous photovoltages. The magnitude of the overall potential drop varies linearly with the total number of domain walls between the electrodes. The thickness dependence of the photovoltage provides another route to verify this conclusion, because the wall density scales inversely with film thickness. From PFM analysis the average domain spacing was calculated and used to calculate a potential drop for each domain wall to be about 10 mV, irrespective of the domain width. This is shown in FIG. 12b, which plots the potential drop in relation to domain width. This value is quite close to the theoretically predicted 20 mV potential drop across 71° domain walls in BFO, represented as a dashed line in FIG. 12b.

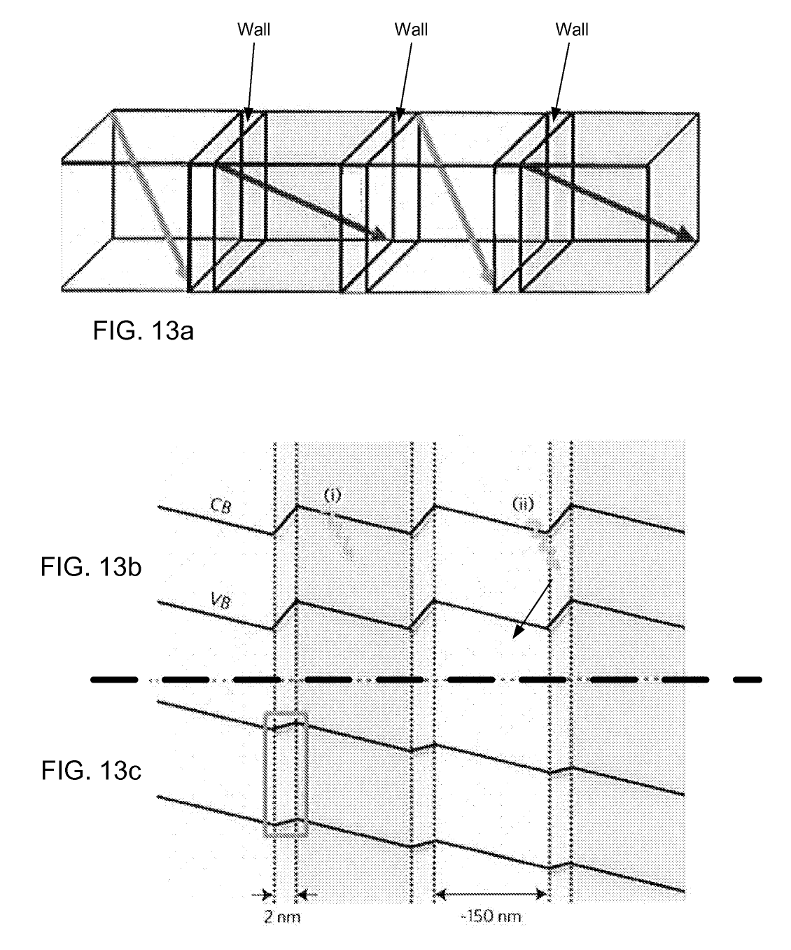

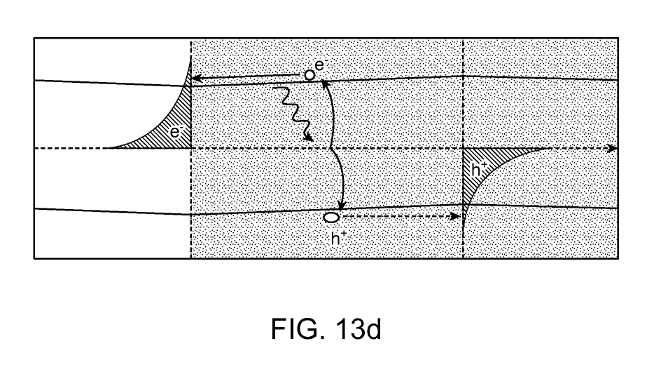

Without necessarily being bound by a particle theory, FIGS. 13a-13d show a model for the effect described above. FIG. 13a is a schematic of the model domain structure showing a series of 71° domain walls, specifically four domains and three domain walls. FIG. 13b shows the corresponding position of the valence (VB) and conduction (CB) bands in dark conditions. There is no net voltage across the sample in the dark. Recent ab initio calculations suggest that ferroelectric domain walls have built-in potential steps arising from the component of the polarization perpendicular to the domain wall. (See Meyer, B. & Vanderbilt, D. Ab initio study of ferroelectric domain walls in PbTiO₃. Phys. Rev. B 65, 104111 (2002) and Seidel, J. et al. Conduction at domain walls in oxide multiferroics. Nature Mater. 8, 229-234 (2009), incorporated by reference herein). The associated charge density, ρ=−∇·P, forms an electric dipole, leading to an electric field within the wall and a potential step from one side to the other. In a strongly correlated, polar system such as BFO, the photo generated exciton is expected to be localized and tightly bound. An exciton in the bulk of the BFO (depicted in FIG. 13b at (i)), is expected to quickly recombine, resulting in no net photo effect. It is believed that if the light is incident at the domain wall (depicted in FIG. 13b at (ii)), the significantly higher local electric field enables a more efficient separation of the excitons, creating a net imbalance in charge carriers near the domain walls and resulting in the band diagram shown in FIG. 13c. This effect (analogous to the type-II band alignment that drives polymeric solar cells) means that, under illumination, a net voltage is observed across the entire sample, resulting from the combined effect of the domain walls and the excess charge carriers created by illumination. Photo excited electron-hole pairs are separated and drift to either side of the domain wall, building up an excess of charge. FIG. 13d depicts a build-up of photo excited charges at a domain wall. A close inspection of the effects at a given domain wall reveals a similar picture to a classic p-n junction. The key difference is the magnitude of the electric field that drives charge separation. In a classic silicon-based system (V_{OC}≈0.7 V; depletion layer thickness, ˜1 μm), an effective electric field of about 7 kV cm⁻¹ is obtained (compared with the BFO system, with a field of about 50 kV cm⁻¹) for each domain wall. In open-circuit illuminated conditions, the electric field across the domain walls should decrease relative to its thermal-equilibrium value, creating a drift-diffusion current equal and opposite to the photocurrent described above. The domains themselves maintain the same electric field as in thermal equilibrium, because this is already the correct field for zero net current. Therefore, a net electric field would build up across the sample as depicted in FIG. 13c.

To validate this model, the bulk photovoltaic effect previously observed in other ferroelectric crystals such as LiNbO₃ (LNO) was ruled out. It is useful to make comparisons with known results on periodically poled LNO, because BFO and LNO have the same symmetry and LNO is an extensively studied photovoltaic ferroelectric material. There have been no reports of large photovoltages being generated in undoped LNO and, because LNO and BFO both have a bulk symmetry R3c, this implies that such high-voltage output in the latter is very unlikely to be a bulk property. Additionally, despite possessing the same bulk symmetry, the domain structures in LNO and BFO are very different. LNO has a rhombohedral-rhombohedral crystal class-preserving ferroelectric phase transition. As a result, it cannot be ferroelastic, and only 180° domain walls can exist. These apparently play no part in any large photovoltage output. In contrast, BFO has a rhombohedral-orthorhombic transition at its Curie temperature. This is a ferroelastic phase transition with 71°, 109° and 180° domain walls. Thus, quantitative differences in photovoltaic response suggest the role of either 71° or 109° domain walls.

Finally, it is noted that the bulk photovoltaic tensor is generally third-rank and non-diagonal in R3c materials such as LNO. Thus, application of an optical field is, in general, affected not only by the r₃₃ photovoltaic coefficient, but also by the r₁₅ coefficient. In a typical experiment on LNO, this off-diagonal term produces a field of 40 kV cm⁻¹ perpendicular to the threefold polar axis for 500 mW of 514.5 nm laser light weakly focused to a 50-μm spot diameter. This number may be compared with those described herein and suggests that a fully quantitative analysis must involve the full off-diagonal photovoltaic tensor. We also note that the photovoltaic response perpendicular to the polar threefold axis can be compensated or enhanced by a strong thermal gradient. Because certain domain walls conduct electricity in BFO, this could involve local heating². Thus, comparison of the described herein data with those for LNO supports the argument that the new effects described herein are not bulk in nature.

Evidence of a completely new photovoltaic mechanism further comes from the fact that the direction of the measured J_{SC} in the BFO films is parallel to the net in-plane polarization. This current direction is opposite to what has been observed for granular ferroelectric materials. In turn, we have observed that there is a drop in the potential in the direction of the net in-plane polarization in these epitaxial BFO films. The expected magnitude of J_{SC} can be predicted, and is consistent with measurements.

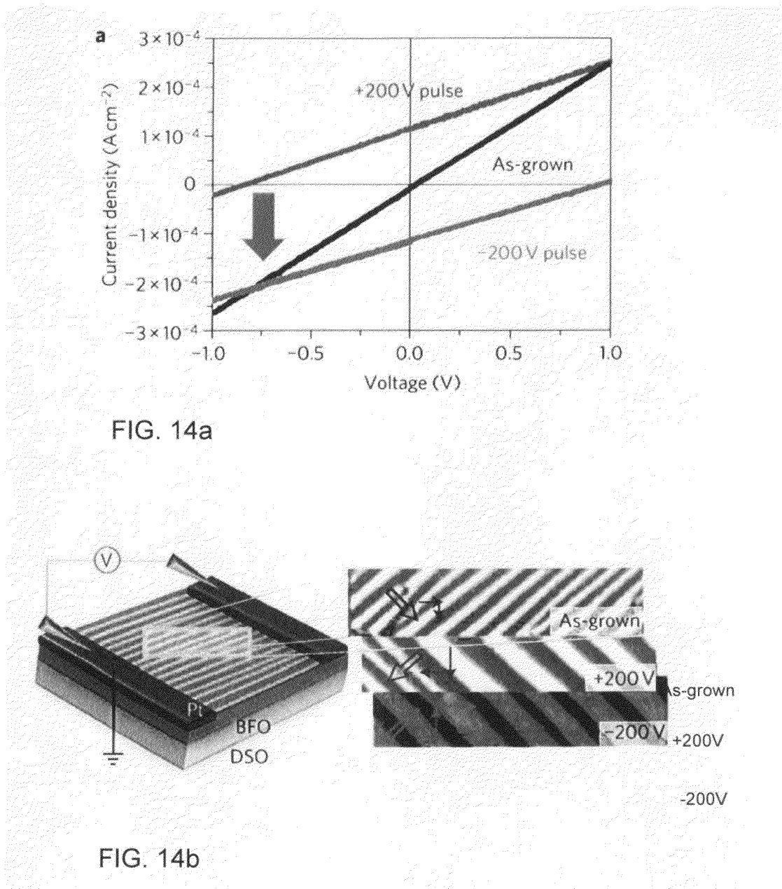

An additional level of control of the photovoltaic effect in these films is demonstrated by the evolution of photovoltaic properties as a function of domain switching in planar device structures. I-V characterization of an as-grown device structure in the DW_{∥} parallel geometry is shown in FIG. 14a. Consistent with data in FIG. 11b, there is no observable photovoltaic response in this geometry. Using a device spacing of 10 μm, voltage pulses of 200 V are applied between the two in-plane electrodes to induce ferroelectric domain switching. Following application of such a field (E 200 kV cm⁻¹) for a pulse of 100 μs, a corresponding rotation of the ferroelectric domain structure was observed, thereby creating a system with the DW_{⊥} (perpendicular) geometry. Subsequent light I-V measurements reveal the formation of an anomalous photovoltaic effect in this film (top curve, FIG. 14a). FIG. 14b shows corresponding PFM images of the as-grown (top panel), 200 V poled (middle panel), and −200 V poled (bottom panel) device structures. The arrows indicate the in-plane projection of the polarization and the net polarization direction for the entire device structure. The corresponding PFM image following the +200 V pulse in FIG. 14b reveal that the domain structure is effectively rotated by 90° from the original configuration (see FIG. 14b, top and middle panels). It is clear that this rotated domain configuration creates the anomalous photovoltaic effect. Furthermore, upon application of a −200 V/100 μs pulse, the polarity of the photo-induced voltage and current can be flipped (bottom curve, 14a). This is explained by a change in the direction of the net, in-plane polarization of the BFO film (FIG. 14b, bottom panel).

Theoretical work shows that the magnitude of the potential step is higher in the case of 109° domain walls (150 mV, compared to 20 mV for 71° domain walls). The presence of a random distribution of the two in-plane variants constrained a macroscopic measurement of the 109° domain samples. However, microscopic measurements revealed about a 4× larger potential drop per domain wall compared to the 71° walls.

A photovoltaic effect in ferroelectric thin films arising from a unique, new mechanism—namely, structurally driven steps of the electrostatic potential at nanometre-scale domain walls is described above. By controlling the domain structure in such films we can, in turn, gain control over the photo properties of these materials.

According to various embodiments, ferroelectric photovoltaic thin film materials are provided. In certain embodiments, the materials include ordered arrays of domain walls. Such arrays may be grown as described in Chu et al., Nanoscale Control of Domain Architectures in BiFeO₃ Thin Films”, Nano Lett. 9, 1726-1730 (2009), incorporated by reference. In one example BFO films of thicknesses between 100 and 500 nm are grown on single-crystalline (110) DyScO₃ (DSO) substrates by metal-organic vapor deposition (MOCVD). Annealing treatments of the DSO substrates (1200° C. for 3 h in flowing O₂) produced ordered arrays of unit cell high terraces on the substrate surface. Growth on such annealed surfaces results in ordered arrays of 71° domain walls, and growth on un0annealed substrates gives rise to ordered arrays of 109° domain walls.

Further details of the above-described novel photovoltaic effect including additional experimental details may be found in Yang et al., Above-bandgap voltages from ferroelectric photovoltaic devices, Nature Nanotechnology, 5, 143-147 and Supplemental Materials available at www.nature.com/naturenanotechnology, all of which are incorporated by reference herein for all purposes.

The high voltages produced by the nanometer-scale domain walls described may be used in various applications. For example, in one application, the devices include a fluid flow path contacting the active ferroic material of the photovoltaic device, with the generated electricity used in electrolytic chemical reactions such as H₂O→H₂+O₂.

According to various embodiments, the photovoltaic devices described herein include two electrodes, and a ferroelectric material including one or more photovoltaic active domain walls (i.e., a domain wall exhibiting the photovoltaic mechanism described above) located between the two electrodes. In certain embodiments, the electrodes and ferroelectric material are arranged such that the domain walls are perpendicular to the direction of electrode-electrode electron transport, though as noted above, in certain embodiments, switchable domain walls are provided.

In certain embodiments, the ferroelectric material includes an ordered array of domain walls. As used herein, an ordered array of domain walls refers a plurality of substantially parallel domain walls. In certain embodiments, the domain walls in a thin film having an ordered array are of a single orientation. For example, in a particular embodiment, an epitaxial rhombohedral perovskite thin film has a plurality of 71° parallel domain walls. In many embodiments, the domain walls have uniform spacing, though this is not necessary. In certain embodiments, there may be walls of multiple orientations in a film, with the walls of the ordered array being of a single or multiple orientations. The domain and domain wall geometry depends on growth conditions and choice of substrate materials. In certain embodiments, to prevent shorting, the thin film does not have domain walls (of any orientation) that are non-parallel to those in the ordered array.

Wall spacing is determined by domain size, and may be between about 10 and 300 nm, e.g., 50 nm and 300 nm with film thickness between about 50 nm and 500 nm, depending on the particular implementation. As indicated above, the walls themselves are typically on the order of 1-3 nanometers. One having ordinary skill will understand that these dimensions may depend on the implementation.

As indicated above, above-bandgap voltages are generated in certain embodiments. Above-bandgap voltages are greater than the semiconductor bandgap of the material. As indicated above, in certain embodiments, the photovoltage scales linearly with the number of domain walls. Voltages of 15-20 V and higher may be generated for a BFO material having a bandgap of less than 3 V.

All materials that exhibit a step in the electrostatic potential at domain walls are candidates for the photovoltaic effect described herein. It is believed that the potential step leads to large built in electric fields at those walls that can drive photovoltaic charge separation. Examples of ferroic materials are given above in the discussion of conducting domain walls, as well as below.

The domain wall orientation varies according to implementation. For example, orthorhombic systems have domain wall orientations of 90° and 180°. Moreover, wall orientations can differ by small amounts from the given values in monoclinic and triclinic systems, which are the lowest forms of symmetry available. A domain wall of any orientation that exhibits the photovoltaic effect described herein may be used.

The substrate layer directly underlying the photovoltaic active material (i.e., the ferroelectric material including one or more domain walls) may be any appropriate material, including a silicon-based substrate such as silicon oxide, DSO, etc. Examples of other substrates include SrTiO₃, PrScO₃, NdScO₃, GdScO₃, LaAlO₃ and YAlO₃. In certain embodiments, it is insulative, e.g., silicon oxide or DSO. In other embodiments, a conductive substrate is used, e.g., for current collection. Similarly, one having skill in the art will understand that conductors may overly the photovoltaic active material for efficient current collection.

Another aspect relates to domain wall magnetism and magnetotransport in ferroic materials. As described above, domain walls in ferroics, including multiferroics, can exhibit behaviors that are significantly different from the bulk. Probing domain walls with x-ray magnetic dichroism based spectromicroscopy, temperature dependent transport, magnetotransport, and exchange coupling to a ferromagnet, demonstrates that the formation of certain types of ferroelectric domain walls (i.e., 109° walls) leads to enhanced magnetic moments in ferroics such as BiFeO₃. The magnetotransport results show the exciting possibility of large magnetoresistance (MR) values. By locally breaking the symmetry of a material, such as at domain walls and structural interfaces, one can induce emergent behavior with properties that significantly deviate from the bulk.

Interfaces have emerged as key focal points of current condensed matter science. In complex, correlated oxides, heterointerfaces provide a powerful route to create and manipulate the charge, spin, orbital, and lattice degrees of freedom. In artificially constructed heterointerfaces, the interaction of such degrees of freedom has resulted in a number of exciting the discoveries including the observation of a 2-D electron gas-like behavior at LaAlO₃—SrTiO₃ interfaces; the emergence of the ferromagnetism in a superconducting material at a YBa₂Cu₃O₇₋ₓ—La_{0.7}Ca_{0.3}MnO₃ interface and more recently in the discovery of a ferromagnetic state induced in a BiFeO₃ (BFO) layer at a heterointerface with La_{0.7}Sr_{0.3}MnO₃. In ferroic oxides, such as ferroelectrics, domain walls emerge as natural interfaces as a consequence of the minimization of electrostatic and/or elastic energies.

Various systems have been explored including classic antiferromagnets such as GdFeO₃; as well as WO₃ and YMnO₃. Among the large number of materials systems currently being explored, the model ferroelectric, antiferromagnet BFO has captured a significant amount of research attention, primarily as a consequence of the fact that the two primary order parameters are robust with respect to room temperature (T_{C}˜820° C., T_{N}˜350° C.). In the case of BFO, certain types of domain walls (i.e., 109° walls) may be important in determining the exchange bias coupling to ferromagnetic layers. Piezomagnetic coupling between ferroelectric and antiferromagnetic domain walls could lead to local moments centered at domain walls and that antiferromagnetic domain wall widths can be significantly larger than ferroelectric domain walls, thereby increasing the net volume of affected material. In addition, the enhanced electrical conduction at specific types of ferroelectric domain walls in BFO (namely 109° and 180° walls) described above provides another example of the connection between atomic, electronic, and magnetic structure in domain walls of these complex materials.

In tetragonal ferroelectrics such as PbTiO₃ two types of domain walls exist, namely 90° and 180° domain walls. In contrast, rhombohedral ferroelectrics (such as BFO) exhibit three types of domain walls, namely those characterized by a 71° rotation (71° walls), a 109°rotation (109° walls), or a 180° rotation of the polarization vector across the domain wall. The first two are both ferroelectric as well as ferroelastic and 71° walls are known to form on 101-type planes (which are symmetry planes for this structure) while 109° walls are known to form on 100-type planes (which are not symmetry planes for the rhombohedral structure). The orientation of the polarization vector changes abruptly (within about 2-3 nm) at the domain walls as imaged by transmission electron microscopy. This can result in a different symmetry inside the domain walls compared to the domains and, in turn, the properties at the walls can also be different.

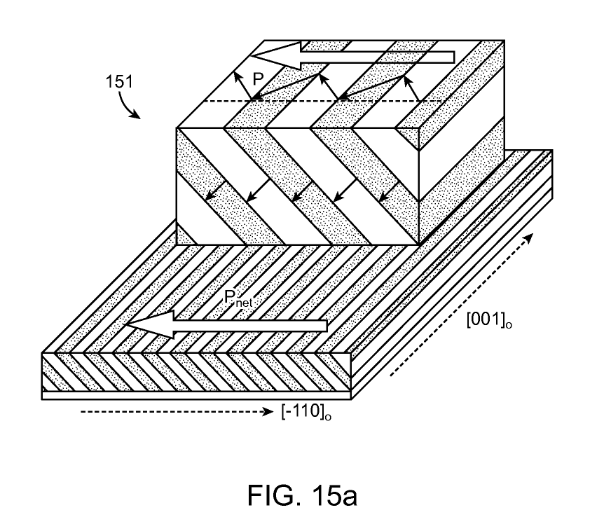

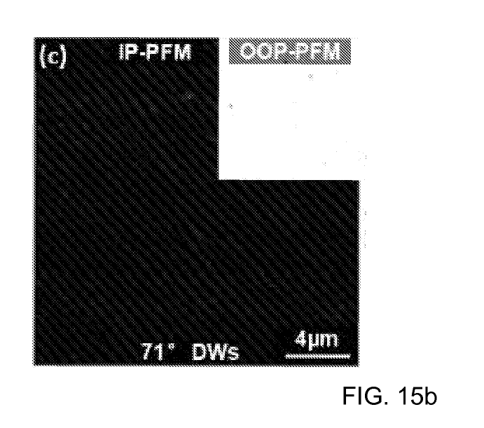

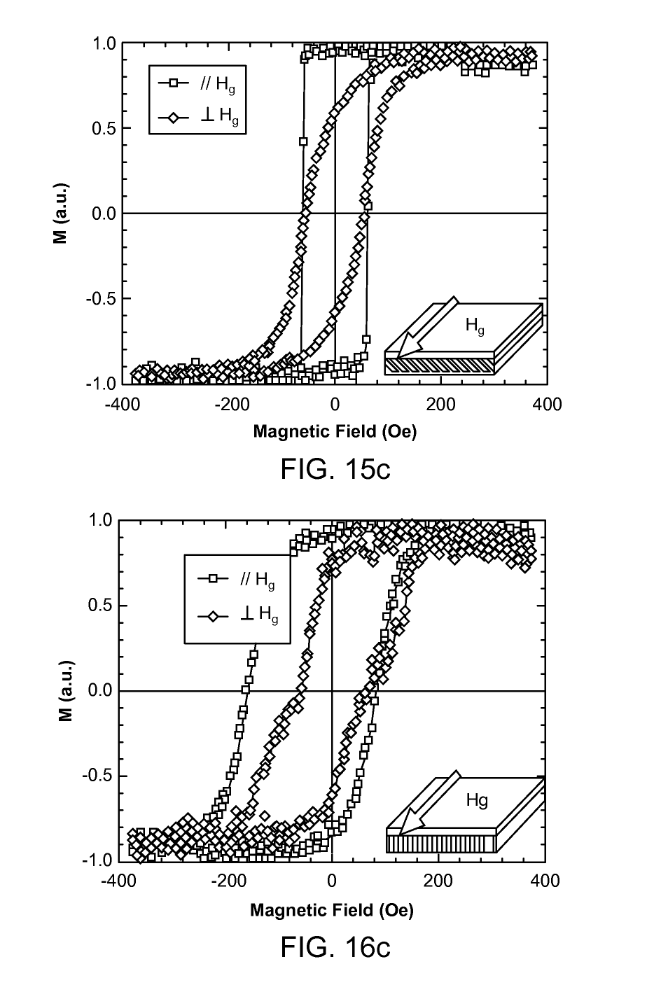

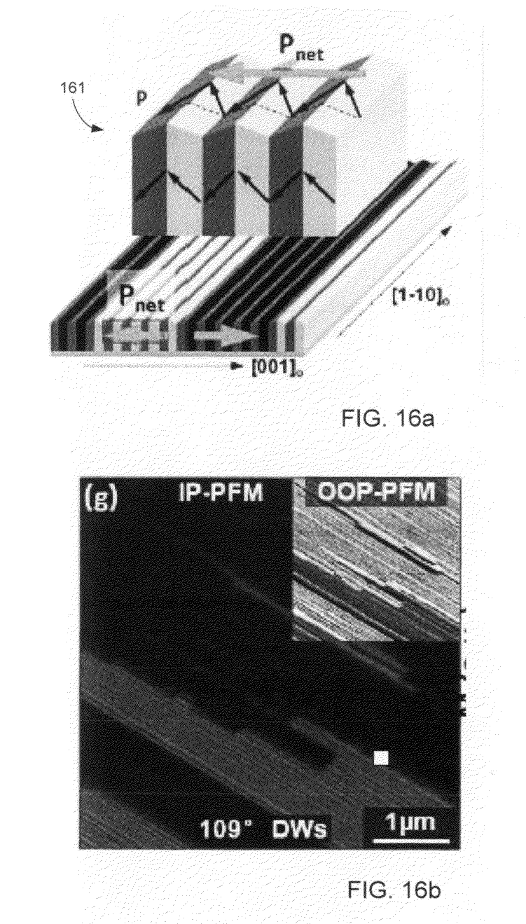

Using an epitaxial growth process that enables control of the electrostatic and elastic boundary conditions in BFO/SrRuO₃ (SRO)/DyScO₃ (110)_{O} heterostructures, ordered arrays of 71° and 109° walls were created. Films grown on thick SRO electrodes (i.e., greater than about 10 nm) show a ferroelectric domain structure that is essentially composed only of periodic arrays of 71° domain walls as imaged via PFM. FIG. 15a provides a schematic, with a detailed description of the nature of polarization in each domain is shown at 151. FIG. 15b provides a PFM image, including the in-plane (IP) and out-of-plane (OOP) PFM image of such a 71° domain wall sample. The OOP PFM image (inset) shows a uniform contrast, indicating a single OOP polarization component that is downward directed (toward the SRO electrode); the in-plane (IP) PFM image shows a stripe pattern with dark (black) and neutral (lighter) contrast, corresponding to domains with the IP components of the polarization directed along [−110]_{pc} and [−1-10]_{pc}. As a consequence of such a domain structure, the net IP component of the polarization of the whole sample points along [−100]_{pc} [arrow, FIG. 15a]. When the SRO bottom electrode thickness is reduced to below about 10 nm (for this study we have used 5 nm), the domain structure changes to become predominantly composed of 109° domains as a consequence of a dominant role of electrostatic effects. FIG. 16a shows a schematic with a detailed description of the polarization directions in each domain in this structure is given at 161. Both the IP and OOP PFM images in FIG. 16b of the 109° domain wall samples show stripe-like contrast. The OOP PFM image shows two contrast levels, dark and bright (FIG. 16b, inset), corresponding to the OOP component of the polarization pointing down and up, while the IP PFM image has three contrast levels—dark (black), neutral (grey), and bright (white). Dark and bright contrast correspond to the IP component of the polarization pointing along [1-10]_{pc} and [−110]_{pc} in different ferroelectric domains as shown in FIG. 16a, while neutral contrast corresponds to the IP component of the polarization pointing either along [−1-10]_{pc} or [110]_{pc}. It is noteworthy that bright and neutral (or dark and neutral) domains are usually grouped together to form bright (dark) “domain bands” that are typically a few microns in width, in which the net polarization is directed in opposite IP directions. Atomic resolution electron microscopy images, obtained using the aberration-corrected microscope (TEAM 0.5) at the National Center for Electron Microscopy, reveal the atomically sharp structure of such walls. These images show that the 109° domain walls are about 2 nm (5 unit cells) wide and form on the 100-type planes while the 71° walls form on the (101)-type planes.

The first indication of significant differences in magnetic behavior between these two types of model ferroelectric domain structures comes from exchange coupling experiments. Heterostructures of Pt (2 nm)/Co_{0.9}Fe_{0.1} (CoFe) were grown at room temperature on BFO/DSO samples with both 71° and 109° domain wall arrays in an ion beam sputtering system with a base pressure of about 5×10⁻¹° Torr. The CoFe films were grown in an applied field of 200 Oe, so as to induce a uniaxial anisotropy. Magnetic measurements were done by surface magneto-optical Kerr effect (SMOKE).

An incident beam was focused onto the sample surface by an optical lens and polarized in the plane of incidence. The angle of incidence of the light was 45° from the sample normal. Upon reflection from the sample surface, the light passed through an analyzing polarizer set at 1° from extinction. The Kerr intensity is then detected by a photodiode and recorded as a function of the in-plane applied magnetic field H to generate a hysteresis loop.

Heterostructures created on BFO films with 71° domain wall arrays exhibit no exchange bias. This is shown in FIG. 15c, which is a hysteresis loop of CoFe on a 71° domain wall sample; curves corresponding to applied magnetic fields antiparallel and perpendicular to the grown magnetic field of CoFe as indicated. On the other hand, samples created from BFO films with 109° domain wall arrays repeatedly exhibited strong negative exchange bias (typical exchange bias field about 40 Oe). FIG. 16c is a hysteresis loop of CoFe on a 109° domain wall sample; curves corresponding to applied magnetic fields antiparallel and perpendicular to the grown magnetic field of CoFe as indicated.

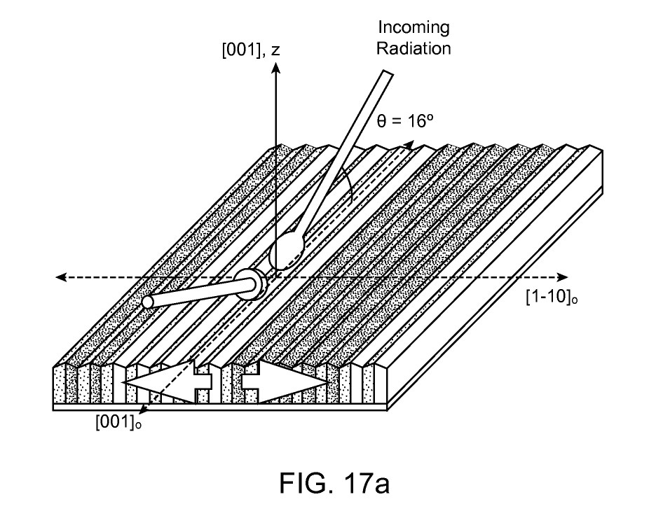

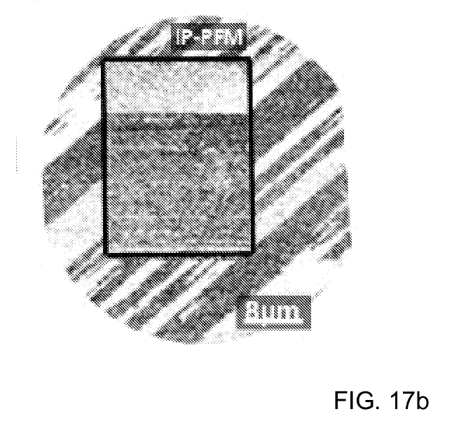

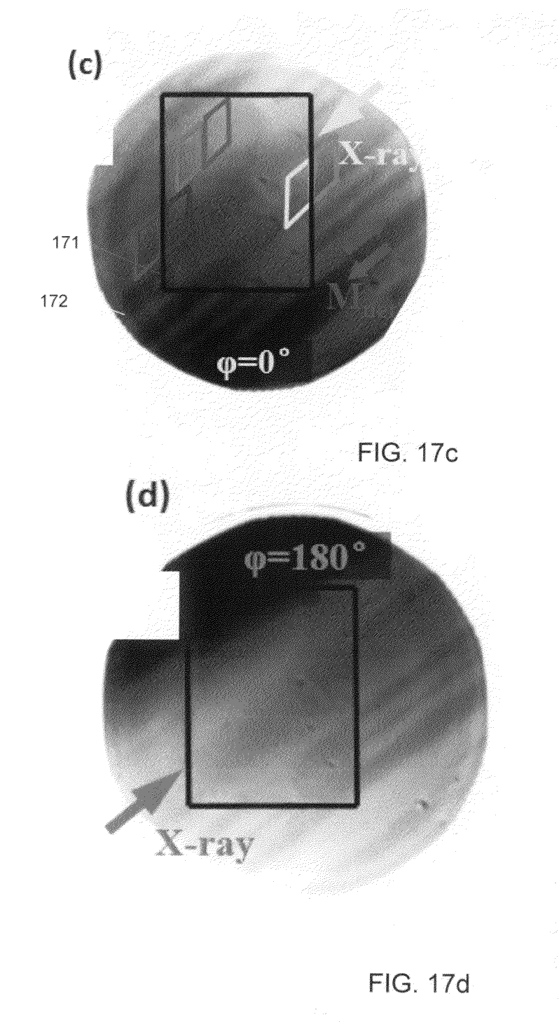

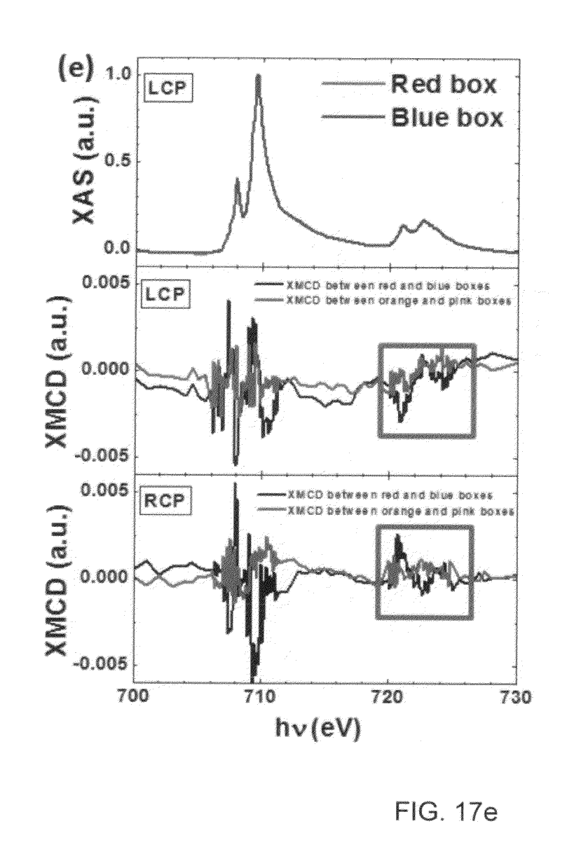

To obtain insight into the local magnetic properties, element specific x-ray spectromicroscopy techniques and magnetotransport, with a strong focus on samples with 109° domain wall arrays, were used. X-ray absorption spectra (XAS) at the Fe L-edge using circularly polarized soft x-rays, at a grazing incidence (θ=16°), while rotating the sample about the surface normal (here we show data for two angles, φ=0°, 180°) of a sample possessing only 109° domain walls was obtained. Spatially resolved photoemission electron microscopy (PEEM) images were obtained using both left- and right-circularly polarized (LCP and RCP, respectively) x-rays at both the Swiss Light Source (Beamline X11MA) and the Advanced Light Source, Berkeley, Calif. (PEEM 3). To enhance the difference in the image contrast between LCP and RCP light, the ratio of the two images was taken. The image contrast is an effective map of the local magnetization vector; regions that have their magnetic moment aligned parallel to the light wave-vector show bright contrast, while those that are antiparallel appear in dark contrast. FIG. 17a is a schematic illustrating the experimental geometries used to take PEEM images of 109° domain walls with circular polarized x-ray. FIG. 17b is an IP-PFM image of the area imaged by PEEM, where the 109° domains are electrically encased within the box.

XMCD-PEEM images with the wave-vector parallel and antiparallel to the domain walls are shown in FIGS. 17c and 17d, respectively. FIG. 17c is a PEEM image obtained from the ratio of LCP and RCP images at the first incident angle of the x-ray. FIG. 17d is a PEEM image at the second incident angle of the x-ray, 180° away from the first angle with respect to the sample normal. For reference, the corresponding in-plane PFM image of the same region is in FIG. 17b, in which the image contrast can be understood based on the analysis discussed above with respect.

With respect to the PEEM images taken 180° from one another in FIGS. 17c and 17d, a striking feature is the observation of dark and bright “bands” of contrast in the image in FIG. 17c; the same features reverse their contrast upon rotation of the sample by 180° in FIG. 17d, identifying the magnetic origin of the contrast. Results of an independent set of measurements carried out on a different sample using the PEEM3 microscope at the Advanced Light Source, Lawrence Berkeley National Laboratory are summarized in were in complete agreement.

Due to the resolution limits of the PEEM technique (PEEM at the SLS has a spatial resolution of about 70 nm under ideal conditions, while PEEM3 has a resolution of about 30-50 nm), the magnetic information from each of the domain walls individually was not resolved individually. To be noted, however, is the fact that bands of 109° domains (composed of an aggregate of individual 109° domain walls, all with the same net in-plane polarization component) also have the same net magnetization direction, as evidenced purely from the image contrast. Within this framework, rotating the sample by 180° reverses the image contrast as shown in FIGS. 17c and 17d.

By applying a dc voltage to the scanning probe tip, areas of 109° domain walls are effectively “erased.” These switching events result in single domain states or in some cases, 71° domain wall ensembles. One such electrically switched region is outlined with a blue box in FIG. 17c. The final ferroelectric domain configuration has been imaged via PFM in FIG. 17b and is shown to have a single ferroelectric domain. If the magnetic contrast arises from the presence of 109° domain walls, electrical switching and erasure of the 109° domain walls would also be accompanied by a corresponding change in the magnetic state of that region. Careful comparison of the image contrast in FIGS. 17c and 17d clearly shows the relative change in contrast from outside the switched box to that inside.

To further validate the conclusions from the PEEM images in FIGS. 17c and 17d, detailed spectroscopic measurements at different points throughout the imaged area were performed. Using circularly polarized light, x-ray absorption spectra (XAS) were obtained from within the switched area as well as from outside; a typical absorption spectrum is shown in FIG. 17e. The normalized difference spectra or the asymmetry between the XAS spectra in the switched and unswitched regions gives us a qualitative measure of the difference in ferromagnetic moment between these two areas. The difference spectrum between an area inside (blue box 171, FIG. 17c) and outside (red box 172, FIG. 17c) the switched box (plotted in FIG. 17e) shows an asymmetry of about 1% at the Fe-edge. When the polarization of the incident x-ray is changed from RCP to LCP, the shape of XMCD curve obtained from these red and blue boxed areas is reversed (see boxed areas in FIG. 17e). Samples with an as-grown 71° domain structure consistently show no measurable asymmetry in the spectra, i.e., no measurable XMCD signal. Furthermore, single domain [111], [110] and [100] oriented films were examined with no measurable XMCD signal observed. These x-ray spectromicroscopy experiments strongly suggest the existence of an enhanced magnetic moment in the samples with 109° domain walls, likely emanating at the walls themselves. This, coupled with the above-described observation of electrical conduction at the same type of domain walls suggests a possibility of observing magnetotransport phenomena at such domain walls.

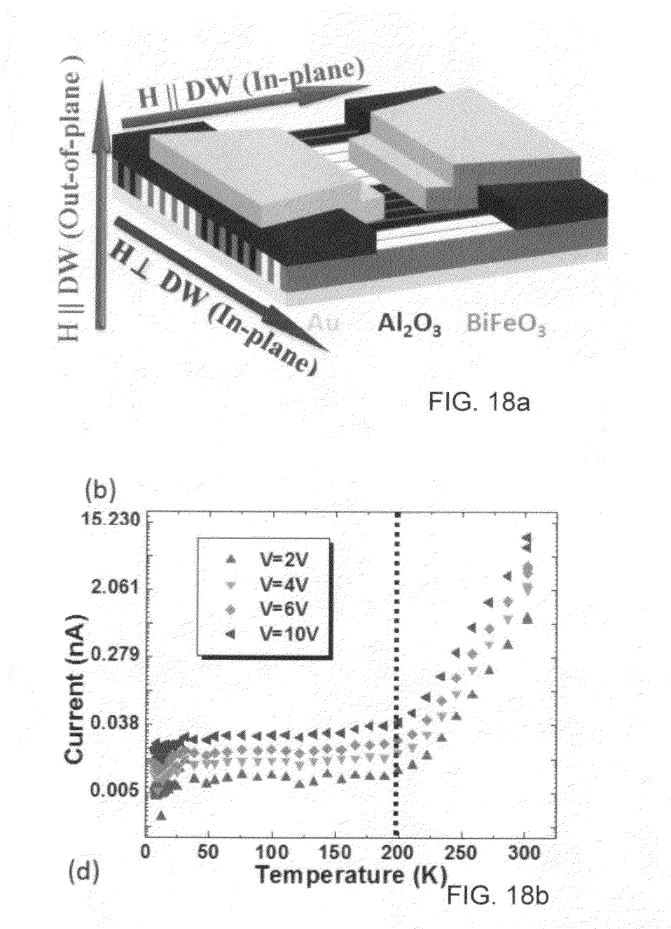

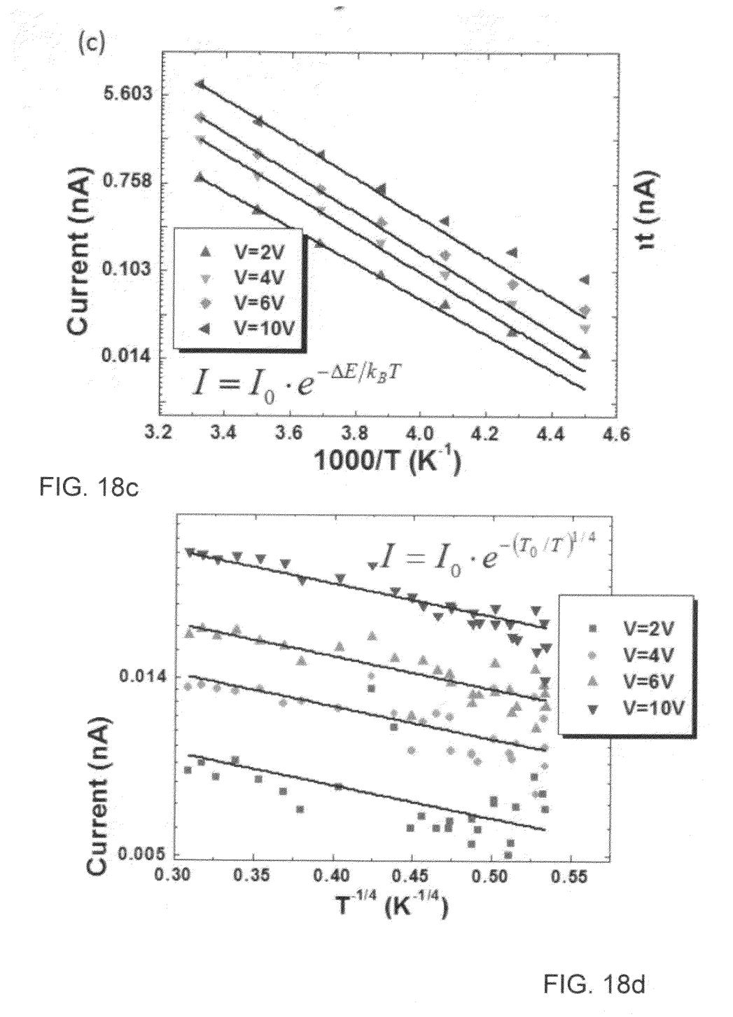

Test structures for in-plane transport measurements were fabricated with 150 nm thick Au electrodes separated by 0.75-1.5 μm; 10 nm thick Al₂O₃ was deposited as an insulating layer to limit the current paths. Au electrodes were fabricated in two geometries relative to the domain wall directions, which restrict the current paths parallel or perpendicular to the domain walls. FIG. 18a is a schematic of a device structure used for the transport sample on 109° domain walls (parallel current path.)

A strong anisotropy of transport (20-50×) between transport parallel and perpendicular to the walls is typically observed. Current-voltage (I-V) curves for test structures with 50 μm and 20 μm contact lengths illustrate the scaling of the total current with the number of domain walls included in the transport path. With the electrode pair restricted to be perpendicular to the domain walls, higher resistances were consistently observed. In contrast, similar devices constructed on 71° domain wall samples exhibit isotropic transport and resistivity between the electrodes in the two orthogonal contact geometries. It is therefore believed that the 109° domain walls, which are much less resistive than the domain area, are the main current paths connecting the in-plane electrodes.

Temperature (4-300K) dependence of transport with the current transport along the 109° domain walls was mapped. FIG. 18b shows Current (I)-Temperature (T) data plotted on a log scale; two distinct regimes are observed. FIG. 18c shows I-T curves above 200K with thermo activation fitting and FIG. 18d shows I-T curves below 160K with variable range hopping fitting. In the high temperature regime (i.e., >200K), the transport can be described by a thermally activated behavior as shown in FIG. 18b for several constant voltage sweeps, with an activation energy of ˜0.25 eV. This transition in transport behavior at ˜200K is intriguing, particularly since phase transitions in BiFeO₃ near 200K have been observed in other work. The activation energy of 0.25 eV observed from the fits of the experimental data is in close agreement with atomic force microscopy based measurements of thermally activated transport in such walls. This activation energy is also consistent with recent calculations of oxygen vacancy trap states in BFO, suggesting that this thermally activated component is arising from detrapping of carriers from oxygen vacancies. At temperatures below 200K, the transport behavior is better described by a variable range hopping (VRH) model (FIG. 18d). The dimensionality of the VRH process, d, can be estimated from the fits to the experimental data; the data agrees well with both a 2-D (i.e., d=2) as well as a 3-D (d=3) transport process. In contrast, the data cannot be fitted to a classical thermally activated transport process (i.e., d=0) or for a 1-D VRH model. It is noted that variable range hopping is commonly observed in doped oxides and specifically has been identified as the low temperature conduction mechanism in other trivalent iron oxides, such as α-Fe₂O₃ and γ-Fe₂O₃.

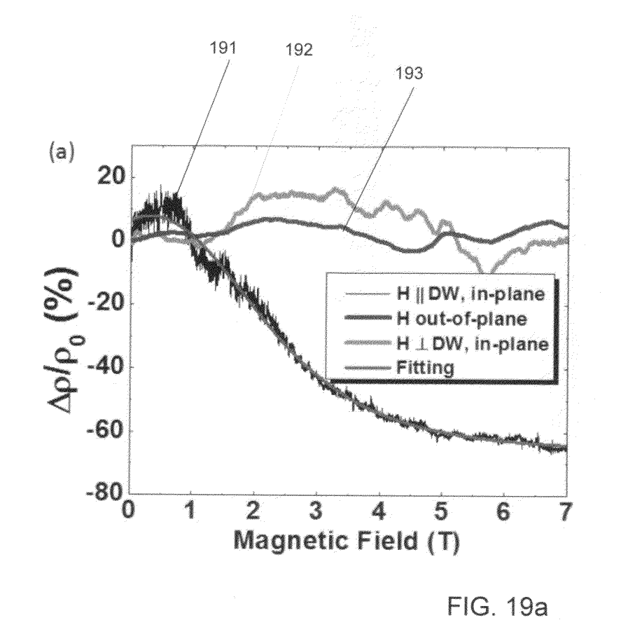

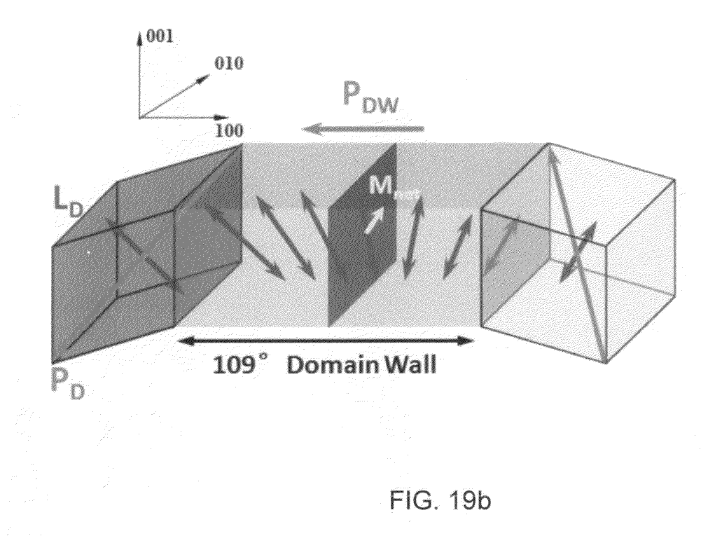

The magnetic field dependence of the transport behavior was investigated, revealing several intriguing aspects. FIG. 19a shows anisotropic magnetoresistance in different direction of external magnetic field as illustrated in FIG. 18a at a temperature of 30K. First, all the samples exhibited a marked negative magnetoresistance (MR) when both magnetic field and transport were parallel to the walls [curve 191, FIG. 19a]. Negative MR values as high as about 60% were obtained at a magnetic field of 7 T. Strikingly when the magnetic field was applied perpendicular to the transport path [both in-plane (curve 192) and out-of-plane (curve 193)] or when the transport is perpendicular to the walls, very little MR is observed, indicating that the MR is directly related to the preferential transport parallel to the walls. In order to understand the microscopic origins of the MR behavior, the intrinsic magnetic order within the two domains on either side of the domain wall is first described. FIG. 19b is a schematic of ferroelectric polarization and the evolution of antiferromagnetic easy axis within one single domain wall with the domain wall plane (100). Several previous experimental studies have shown that the spin spiral in the bulk of BFO is broken when it is grown as a thin film. Further, the degeneracy of the easy plane of magnetization (i.e., {111} in the bulk) is also broken due to the epitaxial strain that is imposed, leading to the formation of an easy antiferromagnetic axis along <11-2> with the ferroelectric polarization along <111> axis. As shown schematically in FIG. 19b, with the domain wall formed in a (100), the domain areas have ferroelectric polarizations pointing along <−1-1-1> and <−111> and antiferromagnetic easy axes pointing along <−1-12> and <1-12>, respectively.

If it is assumed that the antiferromagnetic easy axis rotates smoothly from one domain to the other as one approaches the domain wall from either side; specifically, at the wall, the antiferromagnetic easy axis tracks the angular bisector of the easy axes in the adjacent domains, i.e., it lies along the <0-12> which is in the domain wall plane. This schematic, in the light of the PEEM images in FIGS. 17c and 17d discussed above, strongly suggests the possibility of a preferred easy axis of magnetization parallel to the wall surface [arrow labeled Mnet in FIG. 19b] and the consequent larger MR when measured along the domain wall. With this as the framework, the possible origins of the MR behavior are addressed. The model for the observed MR is based on a modification of the hopping process between spin-clusters in an external magnetic field. Before the application of a magnetic field, the effective moments of each cluster are randomly directed (while the canted moments are aligned in one direction within each spin cluster). With an applied magnetic field, the canted moments of all the spin clusters begin to align along the field direction, and the negative magnetoresistance can be described as a result of reduced resistivity arising from this stronger degree of spin alignment. The magnetoresistance can be calculated as:

$$\frac{ρ ( B ) - ρ ( 0 )}{ρ ( 0 )} = A \cdot \frac{{ρ}_{s} ( B ) + {ρ}_{s} ( 0 )}{{ρ}_{s} ( 0 )} = A \cdot \{ exp \{ - C \cdot {( L ( x ) )}^{2} \} - 1 \}$$

where

$$x = \frac{μ B}{{k}_{B} T} .$$

### Constants A, C, and

$$\frac{μ}{{k}_{B} T}$$

are extracted from fitting the experimental data. The corresponding fit is shown in FIG. 19a, which is reasonably close at a qualitative level. From the fit, the magnitude of

$$\frac{μ}{{k}_{B} T}$$

in the Langevin function as equal to 0.5 T⁻¹ is extracted, which provides insight into the average moment (and therefore size) of the spin clusters. For example, using a measurement temperature of 30K, a cluster moment of ˜22 μ_{B} is calculated. The physical size of the cluster then depends on the magnitude of the canted moment within the walls. A lower bound for the canted moment is the bulk value of about 0.03 μ_{B}; another bound for the canted moment can be estimated from the resolution limit of the PEEM, which is typically about 0.1 μ_{B}. Under these boundary conditions, the spin cluster size is in the range of about 200-550 unit cells in volume (where each unit cell is ˜4×4×4 Å³). Using a wall width of 3-5 unit cells (obtained from atomic resolution images), the lateral size of the spin cluster is estimated to be about 8-14 unit cells (i.e., 3-6 nm).

As described above, enhanced magnetic moments in samples with ordered arrays of 109° domain walls are observed, while samples with ordered arrays of 71° domain walls show no such enhanced magnetic moment. This enhancement correlates to the repeatable observation of an exchange bias in samples that are comprised predominantly of such 109° domain walls. Macroscopic theoretical analyses also point to the emergence of an enhanced magnetic moment at the walls. On a microscopic basis, such an enhancement could be attributed to the symmetry change at 109° domain walls leading to an increase of the canting angle between neighboring Fe spins. It should be noted that the interaction between ferroelectric and antiferromagnetic domain walls has been studied in model multiferroics such as YMnO₃ and BiFeO₃. In both cases it has been shown that the antiferromagnetic domain walls are significantly wider (by about 1-2 orders of magnitude) compared to the ferroelectric walls. It is likely that the enhanced strain as well as the more complex domain wall topology is likely to further enhance the possibility of obtaining larger moments at the domain walls. However, this very complexity is also likely to give a large variability in the observed magnetic moments as has been observed in the case of films grown on SrTiO₃ substrates. As described above, there is a large MR behavior at such walls.

The above description relates to ferroic materials having conductive domain walls, photovoltaic activity, magnetic domain walls and magnetotransport, and related devices. Some examples of ferroic materials are given above. Additional examples are given in the Springer handbook of condensed matter and materials data. (2005), incorporated by reference herein. Categories of ferroic materials that may be used include inorganic crystal oxides, inorganic crystals other than oxides, organic crystals, liquid crystals and polymers.

Inorganic crystal oxides include the perovskite-type family, the LiNbO₃ family, YMnO₃-type family, the SrTeO₃ family, the stibiotantalite family, the tungsten bronze-type family, the pyrochlore-type family, the Sr₂, Nb₂, O₇ family, the layer-structure family, the BaAl₂O₄ type family, the LaBGeO₅ family, the LiNaGe₄O₉ family, the Li₂Ge₇O₁₅ family, the Pb₅Ge₃O₁₁ family, the 5PbO-2P₂O₅ family, Ca₃(VO₄)₂ family, the GMO (Gd₂(MoO₄)₃) family, the boracite-type family and the Rb₃MoO₃F₃ family.

Inorganic crystals other than oxides include the SbSI family, the TIS family, the TiInS₂ family, the KNiCl₃ family, the HCl family, the NaNO₂ family, the BaMnF₄ family, the CsCd(NO₂)₃, the KNO₃ family, the LiH₃(SeO₃)₂ family, the KIO₃ family, the KDP (KH₂PO₄) family, the PbHPO₄ family, the KTiOPO₄ family, the CsCoPO₄ family, the NaTh₂(PO₄)₃ family, the TeOH₆.2NH₄H₂PO₄.(NH₄)₂HPO₄ family, the (NH₄)₂SO₄, NH₄HSO₄ family, the NH₄LiSO₄ family, the (NH₄)₃H(SO₄)₂ family, the lagnebeinite-type family, the leconitte (NaNH₄SO₄.2H₂O) family, the alum family, the GASH(C(NH₂)₃Al(SO₄)₂ family, the colemanite (Ca₂B₆O₁₁.5H₂O) family, the K₄Fe(CN)₆.3H₂O family, and the K₃BiCl₆.2KCl.KH₃F₄ family.

Organic crystals, liquid crystals, and polymers include the SC(NH₂)₂ family, the CCl₃CONH₂ family, the Cu(HCOO₂).4H₂O family, the N(CH₃)₄HgCl₃ family, the (CH₃NH₃)₂AlCl₅.6H2O family, the [(CH₃)₂NH₂]₂CoCl₄ family, the [(CH₃)₂NH₂]₂Sb₂Cl₉ family, the (CH₃NH₃)₅Bi₂Cl₁₁ family, the DSP (Ca₂Sr(CH₃CH₂COO)₆) family, the CH₂ClCOO₂H/NH₄ family, the TGS ((NH₂CH₂COOH)₃.H₂SO₄) family, the NH₂CH₂COOHAgNO₃ family, (NH₂CH₂COOH)₂.HNO₃ family, the (NH₂CH₂COOH)₂.MnCl₂.2H₂O family, the (CH₃NHCH₂COOH)₃.CaCl₂ family, the (CH₃NHCH₃COOH)₃.CaCl₂ family, the (CH₃)₃NCH₂COO.H₃PO₄ family, the (CH₃)₃NCH₂COO.CaCl₂.2H₂O) family, the Rochelle (NaKC₄H₄O₆.4H₂O) family, the LiNH₄C₄H₄O₆.H₂O family, the 3C₆H₄(OH)₂.CH₃OH family, the liquid crystal family and the polymer family.

Further examples include Pb-based materials such as Pb(Zr,Ti)O₃ and PbTiO₃; layered perovskites such as SrBi₂Ta₂O₉ and Bi₄Ti₃O₁₂; BaTiO₃-based materials such as BaTiO₃ and (Ba, Sr)TiO₃; BiVO₄, Bi₂WO₆; LiNbO₃; Pb(ScₓTa₁₋ₓ)O₃; GeTe; PVDF; KNaC₄H₄O₆.4H₂O; KTiOPO₄ and WO₃.

Although the foregoing invention has been described in some detail for purposes of clarity of understanding, it will be apparent that certain changes and modifications may be practiced within the scope of the invention. It should be noted that there are many alternative ways of implementing both the process and compositions of the present invention. Accordingly, the present embodiments are to be considered as illustrative and not restrictive, and the invention is not to be limited to the details given herein.

1. A medium for storing information comprising: a bottom electrode layer, a patterned multiferroic layer overlying the bottom electrode layer, said multiferroic layer comprising a plurality of conductive domain walls separated by insulating domains and arranged in a pattern to store information.

2. The medium of claim 1 wherein the plurality of conductive domain walls are arranged in a pattern to store binary information.

3. The medium of claim 1 wherein the plurality of conductive domain walls are arranged in a pattern to store non-binary information.

4. The medium of claim 1 wherein the multiferroic layer is a multiferroic oxide layer.

5. The medium of claim 1 wherein the multiferroic layer is a ferroelectric oxide layer.

6. The medium of claim 1 wherein the multiferroic layer comprises a bismuth-containing compound.

7. The medium of claim 1 wherein the multiferroic layer comprises a lead-containing compound.

8. The medium of claim 1 wherein the multiferroic layer further comprises non-conducting domain walls.

9. The medium of claim 1 wherein the multiferroic layer comprises bismuth ferrite.

10. The medium of claim 9 wherein at least some of the plurality of conducting domain walls are 109° domain walls.

11. The medium of claim 9 wherein at least some of the plurality of conducting domain walls are 180° domain walls.

12. The medium of claim 1 wherein the smallest domain size is no more than about 50 nm.

13. The medium of claim 1 wherein the smallest domain size is no more than about 10 nm.

14. The medium of claim 1 wherein the allowable pattern density is no more than about 10 nm.

15. The medium of claim 1 wherein the allowable pattern density is no more than about 10 nm.

16. A patterned multiferroic layer comprising a plurality of conductive domain walls separated by insulating domains and arranged in a pattern to store information.

17-38. (canceled)

39. A photovoltaic device comprising:
a substrate; a thin film material ferroelectric material on the insulating substrate, and first and second electrodes in electrical communication with the ferroelectric material, wherein said ferroelectric material includes at least one domain wall located between the first and second electrodes.

40-51. (canceled)
